(19) United States
(12) Patent Application Publication
(10) Pub. No.: US 2024/0170258 A1
(43) Pub. Date: May 23, 2024

(54) PLASMA PROCESSING SYSTEM AND PLASMA PROCESSING METHOD

(71) Applicant: Tokyo Electron Limited, Tokyo (JP)

(72) Inventor: Gen TAMAMUSHI, Kurokawa-gun (JP)

(21) Appl. No.: 18/426,925

(22) Filed: Jan. 30, 2024

Related U.S. Application Data
(63) Continuation of application No. PCT/JP2022/028840, filed on Jul. 26, 2022.

(30) Foreign Application Priority Data
Jul. 30, 2021 (JP) 2021-126097

(51) Int. Cl. H01J 37/32

(52) U.S. Cl. CPC H01J 37/32183; H01J 37/32165; H01J 37/32935

(57) ABSTRACT

A plasma processing system includes a first RF signal generator configured to generate a first RF signal, a first matching circuit coupled to the first RF signal generator, a second RF signal generator configured to generate a second RF signal, a second matching circuit coupled to the second RF signal generator, a first plasma processing apparatus coupled to the first matching circuit and to the second matching circuit, the first RF signal being supplied to the first plasma processing apparatus, and the second RF signal being supplied to the first plasma processing apparatus, and a second plasma processing apparatus coupled to the first matching circuit, the first RF signal being supplied to the second plasma processing apparatus, and the second RF signal of which the phase is shifted being supplied to the second plasma processing apparatus.

### CROSS-REFERENCE TO RELATED APPLICATIONS

The present application is a continuation of and claims priority to PCT/JP2022/028840, filed on Jul. 26, 2022, the entire disclosure of which is incorporated herein by reference.

The present application is based upon and claims the benefit of the prior Japanese Patent Application No. 2021-126097, filed on Jul. 30, 2021, the entire disclosure of which is incorporated herein by reference.

### TECHNICAL FIELD

Exemplary embodiments of the present disclosure relate to a plasma processing system and a plasma processing method.

### BACKGROUND

International Publication No. 2020/227028 discloses an apparatus for matching radio frequency (RF).

### SUMMARY

The present disclosure provides a plasma processing system that can reduce a reflected wave of an RF signal.

In one exemplary embodiment of the present disclosure, a plasma processing system is provided. The plasma processing system comprises a source RF signal generator configured to generate a source RF signal for plasma generation; a first matching circuit coupled to the source RF signal generator; a bias RF signal generator configured to generate a bias RF signal; a second matching circuit coupled to the bias RF signal generator; a phase control circuit coupled to the second matching circuit and configured to shift a phase of the bias RF signal supplied from the bias RF signal generator through the second matching circuit; a first plasma processing apparatus including a first plasma processing chamber and a first substrate support, the first substrate support being disposed in the first plasma processing chamber and including one or a plurality of first lower electrodes, the source RF signal being supplied to the first plasma processing apparatus through the first matching circuit, and the bias RF signal being supplied to at least one of the one or the plurality of first lower electrodes of the first plasma processing apparatus through the second matching circuit; and a second plasma processing apparatus including a second plasma processing chamber and a second substrate support, the second substrate support being disposed in the second plasma processing chamber and including one or a plurality of second lower electrodes, the source RF signal being supplied to the second plasma processing apparatus through the first matching circuit, and the bias RF signal of which the phase is shifted in the phase control circuit being supplied to at least one of the one or the plurality of second lower electrodes of the second plasma processing apparatus.

### BRIEF DESCRIPTION OF DRAWINGS

FIG. 1 is a block diagram illustrating a plasma processing system according to one exemplary embodiment.

FIG. 2 is a block diagram illustrating a configuration of the plasma processing system according to one exemplary embodiment.

FIG. 3 is a diagram schematically illustrating an example of a plasma processing apparatus 1.

FIG. 4A is a diagram illustrating an example of a circuit configuration of a phase control circuit 60.

FIG. 4B is a diagram illustrating an example of the circuit configuration of the phase control circuit 60.

FIG. 5 is a block diagram illustrating the plasma processing system according to one exemplary embodiment.

FIG. 6 is a flowchart illustrating a plasma processing method according to one exemplary embodiment.

FIG. 7 is a timing chart illustrating examples of a source RF signal and a bias RF signal.

FIG. 8 is a timing chart illustrating examples of the source RF signal and the bias RF signal.

FIG. 9 is a diagram illustrating an example of a relationship between a phase of the bias RF signal and sheath capacitance.

FIG. 10 is a block diagram illustrating an example of a configuration of the plasma processing system according to one exemplary embodiment.

FIG. 11 is a block diagram illustrating an example of configurations of a first RF generator 31a, a second RF generator 31b, a first matching circuit 51a, and a second matching circuit 51b.

FIG. 12 is a flowchart illustrating the plasma processing method according to one exemplary embodiment.

FIG. 13 is a timing chart illustrating an example of a period in which a source RF signal SR and a bias RF signal BR1 are supplied.

FIG. 14 is a timing chart illustrating an example of a phase of each bias RF signal.

FIG. 15 is a block diagram illustrating an example of a configuration of the plasma processing system according to one exemplary embodiment.

FIG. 16 is a block diagram illustrating an example of configurations of the first RF generator 31a, a first DC generator 32a, and the first matching circuit 51a.

FIG. 17 is a flowchart illustrating the plasma processing method according to one exemplary embodiment.

FIG. 18 is a timing chart illustrating an example of a period in which the source RF signal SR and a bias DC signal BD1 are supplied.

FIG. 19 is a timing chart illustrating an example of a phase of each bias DC signal.

### DETAILED DESCRIPTION OF DRAWINGS

Hereinafter, each embodiment of the present disclosure will be described.

In one exemplary embodiment, a plasma processing system is provided. The plasma processing system comprises a source RF signal generator configured to generate a source RF signal for plasma generation; a first matching circuit coupled to the source RF signal generator; a bias RF signal generator configured to generate a bias RF signal; a second matching circuit coupled to the bias RF signal generator; a phase control circuit coupled to the second matching circuit and configured to shift a phase of the bias RF signal supplied from the bias RF signal generator through the second matching circuit; a first plasma processing apparatus including a first plasma processing chamber and a first substrate support, the first substrate support being disposed in the first plasma processing chamber and including one or a plurality of first lower electrodes, the source RF signal being supplied to the first plasma processing apparatus through the first matching circuit, and the bias RF signal being supplied to at least one of the one or the plurality of first lower electrodes of the first plasma processing apparatus through the second matching circuit; and a second plasma processing apparatus including a second plasma processing chamber and a second substrate support, the second substrate support being disposed in the second plasma processing chamber and including one or a plurality of second lower electrodes, the source RF signal being supplied to the second plasma processing apparatus through the first matching circuit, and the bias RF signal of which the phase is shifted in the phase control circuit being supplied to at least one of the one or the plurality of second lower electrodes of the second plasma processing apparatus.

In one exemplary embodiment, the phase control circuit includes at least one inductor and at least one capacitor.

In one exemplary embodiment, the phase control circuit includes at least one of a variable inductor or a variable capacitor.

In one exemplary embodiment, a sensor configured to monitor the first RF signal between the first RF signal generator and the first matching circuit and output a monitoring result is further included, in which the phase control circuit is configured to control one or both of inductance of the variable inductor and capacitance of the variable capacitor based on the monitoring result.

In one exemplary embodiment, the sensor is a VI sensor configured to monitor a phase difference of a voltage and a current of the first RF signal.

In one exemplary embodiment, the sensor is a directional coupler configured to monitor a reflected wave of the first RF signal.

In one exemplary embodiment, the phase control circuit is configured to control one or both of inductance of the variable inductor and capacitance of the variable capacitor before or after plasma processing in the second plasma processing apparatus.

In one exemplary embodiment, the phase control circuit is configured to control inductance of the variable inductor and capacitance of the variable capacitor during plasma processing in the second plasma processing apparatus.

In one exemplary embodiment, a phase difference between the second RF signal and the second RF signal of which the phase is shifted is 180 degrees.

In one exemplary embodiment, the first plasma processing apparatus includes a first plasma processing chamber, a first substrate support disposed in the first plasma processing chamber, one or more first lower electrodes disposed in the first substrate support, and a first upper electrode disposed above the first substrate support, the second plasma processing apparatus includes a second plasma processing chamber, a second substrate support disposed in the second plasma processing chamber, one or more second lower electrodes disposed in the second substrate support, and a second upper electrode disposed above the second substrate support, the first matching circuit is coupled to the one or more first lower electrodes or the first upper electrode and to the one or more second lower electrodes or the second upper electrode, the second matching circuit is coupled to the one or more first lower electrodes, and the phase control circuit is coupled to the one or more second lower electrodes.

In one exemplary embodiment, the first plasma processing apparatus includes a first plasma processing chamber, a first substrate support disposed in the first plasma processing chamber, a first lower electrode disposed in the first substrate support, and a first antenna disposed above the first plasma processing chamber, the second plasma processing apparatus includes a second plasma processing chamber, a second substrate support disposed in the second plasma processing chamber, a second lower electrode disposed in the second substrate support, and a second antenna disposed above the second plasma processing chamber, the first matching circuit is coupled to the first antenna and to the second antenna, the second matching circuit is coupled to the first lower electrode, and the phase control circuit is coupled to the second lower electrode.

In one exemplary embodiment, the first frequency is greater than or equal to 10 MHz and less than or equal to 120 MHz.

In one exemplary embodiment, the second frequency is greater than or equal to 100 kHz and less than or equal to 20 MHz.

In one exemplary embodiment, the second frequency is greater than or equal to 400 kHz and less than or equal to 4 MHZ.

In one exemplary embodiment, the first RF signal is a continuous wave having a first frequency.

In one exemplary embodiment, the first RF signal is a pulse wave periodically including a plurality of first electrical pulses, and each of the plurality of first electrical pulses includes a continuous wave having a first frequency. In one exemplary embodiment, the second RF signal is a continuous wave having a second frequency.

In one exemplary embodiment, the second RF signal is a pulse wave periodically including a plurality of second electrical pulses, and each of the plurality of second electrical pulses includes a continuous wave having a second frequency.

In one exemplary embodiment, a plasma processing method executed in a plasma processing system including a first plasma processing apparatus and a second plasma processing apparatus is provided. The plasma processing method includes generating a first RF signal having a first frequency, generating a second RF signal having a second frequency lower than the first frequency, shifting a phase of the second RF signal, supplying the first RF signal to the first plasma processing apparatus and to the second plasma processing apparatus, supplying the second RF signal to the first plasma processing apparatus, and supplying the second RF signal of which the phase is shifted to the second plasma processing apparatus.

In one exemplary embodiment, a plasma processing system is provided. The plasma processing system comprises an RF signal generator configured to generate an RF signal; a matching circuit coupled to the RF signal generator; a voltage pulse generator configured to generate a sequence of voltage pulses; a phase control circuit configured to shift phases of the sequence of voltage pulses supplied from the voltage pulse generator; a first plasma processing apparatus including a first plasma processing chamber and a first substrate support, the first substrate support being disposed in the first plasma processing chamber and including one or a plurality of first lower electrodes, the RF signal being supplied to the first plasma processing apparatus through the matching circuit, and the sequence of voltage pulses being supplied to the one or the plurality of first lower electrodes of the first plasma processing apparatus from the voltage pulse generator; and a second plasma processing apparatus including a second plasma processing chamber and a second substrate support, the second substrate support being disposed in the second plasma processing chamber and including one or a plurality of second lower electrodes, the RF signal being supplied to the second plasma processing apparatus through the matching circuit, and the sequence of voltage pulses of which the phases are shifted in the phase control circuit being supplied to at least one of the one or the plurality of second lower electrodes of the second plasma processing apparatus.

In one exemplary embodiment, a plasma processing system is provided. The plasma processing system comprising: a source RF signal generator configured to generate a source RF signal for plasma generation; a first matching circuit coupled to the source RF signal generator; a bias RF signal generator configured to generate a bias RF signal; a second matching circuit coupled to the bias RF signal generator; n plasma processing apparatuses (n is an integer greater than or equal to 2) coupled in parallel to the first matching circuit; and (n−1) phase control circuits, wherein the (n−1) phase control circuits are coupled in series between the second matching circuit and an n-th plasma processing apparatus among the n plasma processing apparatuses and are configured to sequentially shift a phase of the bias RF signal supplied from the bias RF signal generator through the second matching circuit, a k-th (k is an integer of 1 to n−1) phase control circuit among the (n−1) phase control circuits is coupled to a k-th plasma processing apparatus and to a (k+1)-th plasma processing apparatus among the n plasma processing apparatuses, a first plasma processing apparatus among the n plasma processing apparatuses includes a first plasma processing chamber and a first substrate support, in which the first substrate support is disposed in the first plasma processing chamber and includes one or a plurality of first lower electrodes, the source RF signal is supplied to the first plasma processing apparatus through the first matching circuit, and the bias RF signal is supplied to at least one of the one or the plurality of first lower electrodes of the first plasma processing apparatus through the second matching circuit, and the (k+1)-th plasma processing apparatus among the n plasma processing apparatuses includes a (k+1)-th plasma processing chamber and a (k+1)-th substrate support, the (k+1)-th substrate support being disposed in the (k+1)-th plasma processing chamber and including one or a plurality of (k+1)-th lower electrodes, the source RF signal being supplied to the (k+1)-th plasma processing apparatus through the first matching circuit, and the bias RF signal of which the phase is shifted in the k-th phase control circuit among the (n−1) phase control circuits being supplied to at least one of the one or the plurality of (k+1)-th lower electrodes of the (k+1)-th plasma processing apparatus.

In one exemplary embodiment, the (n−1) phase control circuits are configured to sequentially shift the phase of the bias RF signal by 360 degrees/n.

In one exemplary embodiment, the plasma processing system further includes n first switches that switch whether or not each of the n plasma processing apparatuses is coupled to the first matching circuit, and n second switches that switch whether or not each of the n plasma processing apparatuses is coupled to the second matching circuit.

In one exemplary embodiment, a plasma processing system is provided. The plasma processing system comprising: a source RF signal generator configured to generate a source RF signal for plasma generation; a first matching circuit coupled to the source RF signal generator; a voltage pulse generator configured to generate n (n is an integer greater than or equal to 2) sequences of voltage pulses, the phases of the n sequences of voltage pulses are different from each other; and n plasma processing apparatuses, wherein a k-th (k is an integer of 1 to n) plasma processing apparatus among the n plasma processing apparatuses includes a k-th plasma processing chamber and a k-th substrate support, the k-th substrate support is disposed in the k-th plasma processing chamber and includes one or a plurality of the k-th lower electrodes, the source RF signal is supplied to the k-th plasma processing apparatus through the first matching circuit, and a k-th sequence of voltage pulses in the n sequences of voltage pulses is supplied to at least one of the one or the plurality of k-th lower electrodes of the k-th plasma processing apparatus.

Hereinafter, each embodiment of the present disclosure will be described in detail with reference to the drawings. The same or similar elements in each drawing will be designated by the same reference signs, and duplicate descriptions of the elements will be omitted. Unless otherwise specified, a positional relationship such as up, down, left, and right will be described based on the positional relationship illustrated in the drawings. Dimensional ratios in the drawings do not indicate actual ratios, and the actual ratios are not limited to the illustrated ratios.

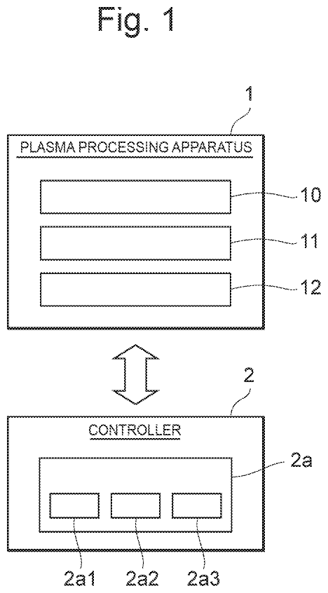

FIG. 1 is a block diagram illustrating a plasma processing system according to one exemplary embodiment. The plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40, described later. The substrate support 11 is disposed in the plasma processing space and has a substrate support surface for supporting a substrate.

The plasma generator 12 is configured to generate a plasma from at least one processing gas supplied into the plasma processing space. The plasma generated in the plasma processing space may be a capacitively coupled plasma (CCP), an inductively coupled plasma (ICP), an electron-cyclotron-resonance plasma (ECR), a helicon wave plasma (HWP), a surface wave plasma (SWP), or the like. In addition, various types of plasma generators including an alternating current (AC) plasma generator and a direct current (DC) plasma generator may be used. In one embodiment, an AC signal (AC power) used in the AC plasma generator has a frequency within a range of 100 KHz to 10 GHZ. Accordingly, the AC signal includes a radio frequency (RF) signal and a microwave signal. In one embodiment, the RF signal has a frequency within a range of 200 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In one embodiment, a part or the entirety of the controller 2 may be included in the plasma processing apparatus 1. The controller 2 may include, for example, a computer 2a. The computer 2a may include, for example, a processor (central processing unit (CPU)) 2a1, a storage 2a2, and a communication interface 2a3. The processor 2a1 may be configured to perform various control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN).

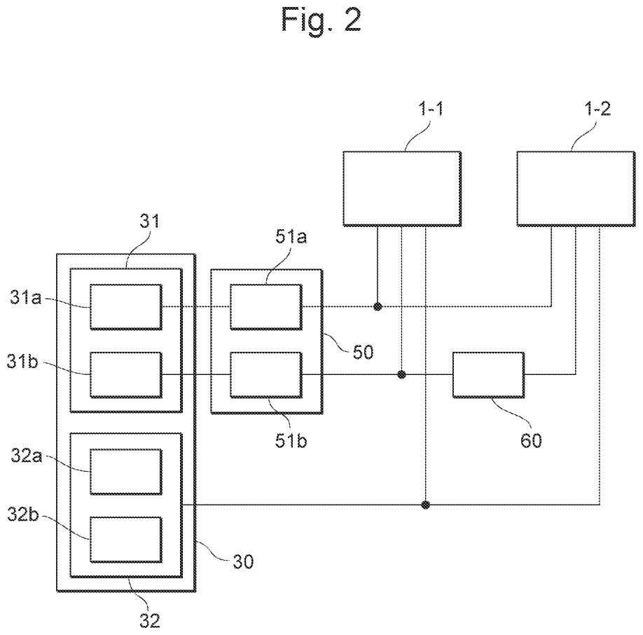

FIG. 2 is a block diagram illustrating a configuration of the plasma processing system according to one exemplary embodiment. The plasma processing system includes a first plasma processing apparatus 1-1, a second plasma processing apparatus 1-2, a power supply 30, an impedance matching circuit 50, and a phase control circuit 60. In one embodiment, the first plasma processing apparatus 1-1 includes a first plasma processing chamber, a first substrate support disposed in the first plasma processing chamber, a first lower electrode disposed in the first substrate support, and a first upper electrode disposed above the first substrate support. The second plasma processing apparatus 1-2 includes a second plasma processing chamber, a second substrate support disposed in the second plasma processing chamber, a second lower electrode disposed in the second substrate support, and a second upper electrode disposed above the second substrate support. Hereinafter, the first plasma processing apparatus 1-1 and/or the second plasma processing apparatus 1-2 will be collectively referred to as the “plasma processing apparatus 1”.

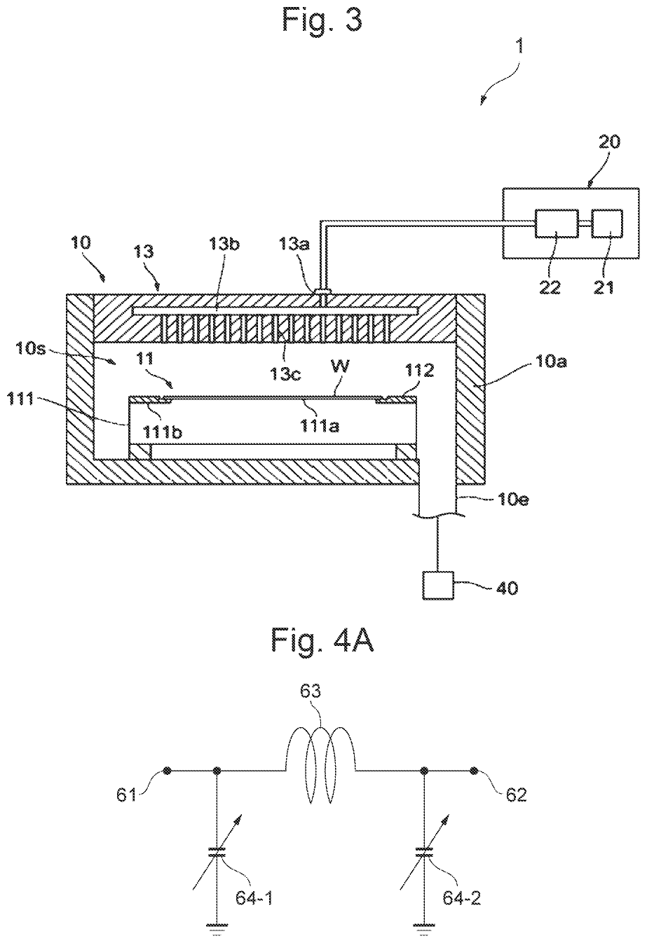

FIG. 3 is a diagram schematically illustrating an example of the plasma processing apparatus 1. Hereinafter, a configuration example of a capacitively coupled plasma processing apparatus as an example of the plasma processing apparatus 1 will be described with reference to each drawing.

The plasma processing apparatus 1 includes the plasma processing chamber 10, the gas supply 20, and the exhaust system 40. In addition, the plasma processing apparatus 1 includes the substrate support 11 and a gas introducer. The gas introducer is configured to introduce at least one processing gas into the plasma processing chamber 10. The gas introducer includes a showerhead 13. The substrate support 11 is disposed in the plasma processing chamber 10. The showerhead 13 is disposed above the substrate support 11. In one exemplary embodiment, the showerhead 13 constitutes at least a part of a ceiling of the plasma processing chamber 10. The plasma processing chamber 10 has a plasma processing space 10s defined by the showerhead 13, side walls 10a of the plasma processing chamber 10, and the substrate support 11. The plasma processing chamber 10 has at least one gas supply port for supplying at least one processing gas to the plasma processing space 10s and at least one gas exhaust port for exhausting the gas from the plasma processing space. The side walls 10a are grounded. The showerhead 13 and the substrate support 11 are electrically insulated from a housing of the plasma processing chamber 10.

The substrate support 11 includes a main body 111 and a ring assembly 112. The main body 111 has a center region (substrate support surface) 111a for supporting a substrate (wafer) W and a ring-shaped region (ring support surface) 111b for supporting the ring assembly 112. The ring-shaped region 111b of the main body 111 surrounds the center region 111a of the main body 111 in a plan view. The substrate W is disposed on the center region 111a of the main body 111, and the ring assembly 112 is disposed on the ring-shaped region 111b of the main body 111 to surround the substrate W on the center region 111a of the main body 111. In one embodiment, the main body 111 includes a base and an electrostatic chuck. The base includes a conductive member. The conductive member of the base may function as a lower electrode. The electrostatic chuck is disposed on the base. The electrostatic chuck includes a ceramic member and an electrostatic electrode disposed in the ceramic member. The ceramic member has the center region 111a. In one embodiment, the ceramic member also has the ring-shaped region. Another member that surrounds the electrostatic chuck, such as a ring-shaped electrostatic chuck or a ring-shaped insulation member, may have the ring-shaped region. In this case, the ring assembly 112 may be disposed on the ring-shaped electrostatic chuck or on the ring-shaped insulation member or may be disposed on both of the electrostatic chuck and the ring-shaped insulation member. In addition, an RF or DC electrode may be disposed in the ceramic member. In this case, the RF or DC electrode may function as a lower electrode. In a case where a bias RF signal or a DC signal, described later, is supplied to the RF or DC electrode, the RF or DC electrode is referred to as a bias electrode. Both of the conductive member of the base and the RF or DC electrode may function as a lower electrode. Accordingly, the substrate support 11 includes one or more lower electrodes. The ring assembly 112 includes one or a plurality of ring-shaped members. At least one of the one or the plurality of ring-shaped members is an edge ring. In addition, while illustration is not provided, the substrate support 11 may include a temperature control module configured to control at least one of the electrostatic chuck, the ring assembly 112, or the substrate to have a target temperature. The temperature control module may include a heater, a heat transfer medium, a flow path, or a combination thereof. A heat transfer fluid such as brine or gas flows through the flow path. In addition, the substrate support 11 may include a heat transfer gas supply configured to supply a heat transfer gas between a rear surface of the substrate W and the substrate support surface 111a.

The showerhead 13 (refer to FIG. 3) is configured to introduce at least one processing gas from the gas supply 20 into the plasma processing space 10s. The showerhead 13 has at least one gas supply port 13a, at least one gas diffusion chamber 13b, and a plurality of gas introduction ports 13c. A processing gas supplied to the gas supply port 13a passes through the gas diffusion chamber 13b and is introduced into the plasma processing space 10s from the plurality of gas introduction ports 13c. In addition, the showerhead 13 includes one or more upper electrodes. In addition to the showerhead 13, the gas introducer may include one or a plurality of side gas injectors (SGI) attached to one or a plurality of opening portions formed on the side walls 10a.

The gas supply 20 may include at least one gas source 21 and at least one flow controller 22. In one embodiment, the gas supply 20 is configured to supply at least one processing gas to the showerhead 13 from each corresponding gas source 21 through each corresponding flow controller 22. Each flow controller 22 may include, for example, a mass flow controller or a pressure-controlled flow controller. Furthermore, the gas supply 20 may include at least one flow modulation device that modulates or pulses a flow of at least one processing gas.

The power supply 30 includes an RF power supply 31 coupled to the plasma processing chamber 10 through at least one impedance matching circuit 50. The RF power supply 31 is configured to supply at least one RF signal (RF power) such as a source RF signal and a bias RF signal to one or more lower electrodes and/or one or more upper electrodes. Accordingly, a plasma is generated from at least one processing gas supplied to the plasma processing space 10s. Thus, the RF power supply 31 may function as at least a part of the plasma generator 12. In addition, by supplying the bias RF signal to one or more lower electrodes, a bias potential is generated in the substrate W, and ion components in the generated plasma can be drawn to the substrate W.

In one embodiment, the RF power supply 31 includes a first RF generator 31a and a second RF generator 31b. The first RF generator 31a is coupled to one or more lower electrodes and/or one or more upper electrodes through at least one matching circuit 51a and is configured to generate the source RF signal (source RF power) for plasma generation. The first RF generator 31a is an example of a source RF signal generator. In one embodiment, the source RF signal is a continuous or pulse wave configured to include an RF having a frequency within a range of 10 MHZ to 150 MHz. In one embodiment, the first RF generator 31a may be configured to generate a plurality of source RF signals having different frequencies. The generated one or the plurality of source RF signals is supplied to one or more lower electrodes and/or one or more upper electrodes. In one embodiment, the first RF generator 31a is configured to generate a first continuous or pulsed RF signal having a first frequency as the source RF signal.

The first matching circuit 51a is coupled to the first RF generator 31a. In addition, the first plasma processing apparatus 1-1 and the second plasma processing apparatus 1-2 are coupled to the first matching circuit 51a. That is, the first matching circuit 51a is coupled to one or more upper electrodes or one or more lower electrodes of the first plasma processing apparatus 1-1 and is coupled to one or more upper electrodes or one or more lower electrodes of the second plasma processing apparatus 1-2. Accordingly, a first source RF signal that is generated is supplied to one or more lower electrodes or one or more upper electrodes of the first plasma processing apparatus 1-1 and to one or more lower electrodes or one or more upper electrodes of the second plasma processing apparatus 1-2 through the first matching circuit 51a. That is, the source RF signal is supplied to one or more lower electrodes or one or more upper electrodes of the first plasma processing apparatus 1-1 and to one or more lower electrodes or one or more upper electrodes of the second plasma processing apparatus 1-2 from the first matching circuit 51a.

The second RF generator 31b is coupled to one or more lower electrodes through at least one matching circuit 51b and is configured to generate the bias RF signal (bias RF power). The second RF generator 31b is an example of a bias RF signal generator. In a case where one or more lower electrodes include two lower electrodes, one lower electrode may be coupled to the first RF generator 31a through the matching circuit 51a, and the other lower electrode may be coupled to the second RF generator 31b through the matching circuit 51b. For example, the one lower electrode may be the base, and the other lower electrode may be the bias electrode.

In one embodiment, the bias RF signal has a lower frequency than the source RF signal. In one embodiment, the bias RF signal is a continuous or pulse wave configured to include an RF having a frequency within a range of 100 kHz to 60 MHz. In one embodiment, the second RF generator 31b may be configured to generate a plurality of bias RF signals having different frequencies. The generated one or the plurality of bias RF signals is supplied to one or more lower electrodes. In addition, in various embodiments, at least one of the source RF signal or the bias RF signal may be pulsed. In one embodiment, the second RF generator 31b is configured to generate a second continuous or pulsed RF signal having a second frequency lower than the first frequency as the bias RF signal.

The second matching circuit 51b is coupled to the second RF generator 31b. In addition, the first plasma processing apparatus 1-1 and the phase control circuit 60 are coupled to the second matching circuit 51b, and the second plasma processing apparatus 1-2 is coupled to the phase control circuit 60. That is, the second matching circuit 51b is coupled to one or more lower electrodes of the first plasma processing apparatus 1-1. Accordingly, the generated bias RF signal is supplied to one or more lower electrodes of the first plasma processing apparatus 1-1 and to the phase control circuit 60 through the second matching circuit 51b. That is, the bias RF signal is supplied to one or more lower electrodes of the first plasma processing apparatus 1-1 and to the phase control circuit 60 from the second matching circuit 51b. A phase of the bias RF signal supplied to the phase control circuit 60 from the second RF generator 31b through the second matching circuit 51b is shifted in the phase control circuit 60. The phase control circuit 60 is coupled to the second plasma processing apparatus 1-2, that is, one or more lower electrodes of the second plasma processing apparatus 1-2. Accordingly, the bias RF signal of which the phase is shifted is supplied to one or more lower electrodes of the second plasma processing apparatus 1-2 from the phase control circuit 60.

In addition, the power supply 30 may include a DC power supply 32 coupled to the plasma processing chamber 10. The DC power supply 32 includes a first DC generator 32a and a second DC generator 32b. In one embodiment, the first DC generator 32a is connected to one or more lower electrodes and is configured to generate a first DC signal. The generated first DC signal is applied to one or more lower electrodes. In one embodiment, the first DC signal may be applied to another electrode such as the electrode in the electrostatic chuck.

In one embodiment, the second DC generator 32b is connected to one or more upper electrodes and is configured to generate a second DC signal. The generated second DC signal is applied to one or more upper electrodes.

In various embodiments, the first and second DC signals may be pulsed. In this case, a sequence of voltage pulses is applied to one or more lower electrodes and/or one or more upper electrodes. The voltage pulses may have a pulse waveform of a rectangular shape, a trapezoidal shape, a triangular shape, or a combination thereof. In one embodiment, a waveform generator for generating the sequence of voltage pulses from the DC signal is connected between the first DC generator 32a and one or more lower electrodes. Accordingly, the first DC generator 32a and the waveform generator constitute a voltage pulse generator. In a case where the second DC generator 32b and the waveform generator constitute the voltage pulse generator, the voltage pulse generator is connected to one or more upper electrodes.

The voltage pulses may have a positive polarity or a negative polarity. In addition, the sequence of voltage pulses may include one or a plurality of positive voltage pulses and one or a plurality of negative voltage pulses in one cycle. The first and second DC generators 32a and 32b may be provided in addition to the RF power supply 31, or the first DC generator 32a may be provided instead of the second RF generator 31b. In the latter case, as illustrated in FIG. 5, the phase control circuit 60 is connected between the voltage pulse generator including the first DC generator 32a and one or more lower electrodes of the second plasma processing apparatus 1-2 without a matching circuit. In one embodiment, the voltage pulse generator including the first DC generator 32a is coupled to one or more lower electrodes of the first plasma processing apparatus 1-1 and to the phase control circuit 60. Accordingly, the sequence of voltage pulses generated by the voltage pulse generator including the first DC generator 32a is supplied to one or more lower electrodes of the first plasma processing apparatus 1-1 and to the phase control circuit 60. Phases of the sequence of voltage pulses supplied to the phase control circuit 60 from the voltage pulse generator including the first DC generator 32a are shifted in the phase control circuit 60. The phase control circuit 60 is coupled to one or more lower electrodes of the second plasma processing apparatus 1-2. Accordingly, the sequence of voltage pulses of which the phase is shifted is supplied to one or more lower electrodes of the second plasma processing apparatus 1-2 from the phase control circuit 60.

The impedance matching circuit 50 has the first matching circuit 51a and the second matching circuit 51b. The first matching circuit 51a has an input terminal and an output terminal. The input terminal is electrically coupled to the first RF generator 31a. In addition, the output terminal is electrically coupled to the substrate support 11 or the showerhead 13 provided in the first plasma processing apparatus 1-1 and to the substrate support 11 or the showerhead 13 provided in the second plasma processing apparatus 1-2. The first matching circuit 51a controls impedance of the output terminal with respect to impedance of the input terminal. For example, the first matching circuit 51a causes the impedance of the input terminal and the impedance of the output terminal to match. The impedance of the input terminal may be output impedance of the first RF generator 31a. In addition, the impedance of the output terminal may include a load of the plasma generated in each of the first plasma processing apparatus 1-1 and the second plasma processing apparatus 1-2. The second matching circuit 51b has an input terminal and an output terminal. The input terminal is electrically coupled to the second RF generator 31b. In addition, the output terminal is electrically coupled to the substrate support 11 provided in the first plasma processing apparatus 1-1 and to the substrate support 11 provided in the second plasma processing apparatus 1-2. The second matching circuit 51b controls impedance of the output terminal with respect to impedance of the input terminal. For example, the second matching circuit 51b causes the impedance of the input terminal and the impedance of the output terminal to match. The impedance of the input terminal may be output impedance of the second RF generator 31b. In addition, the impedance of the output terminal may include the load of the plasma generated in each of the first plasma processing apparatus 1-1 and the second plasma processing apparatus 1-2.

The phase control circuit 60 receives a first bias RF signal from the second RF generator 31b through the second matching circuit 51b. The phase control circuit 60 generates a second bias RF signal having a phase difference with respect to the first bias RF signal by shifting a phase of the first bias RF signal.

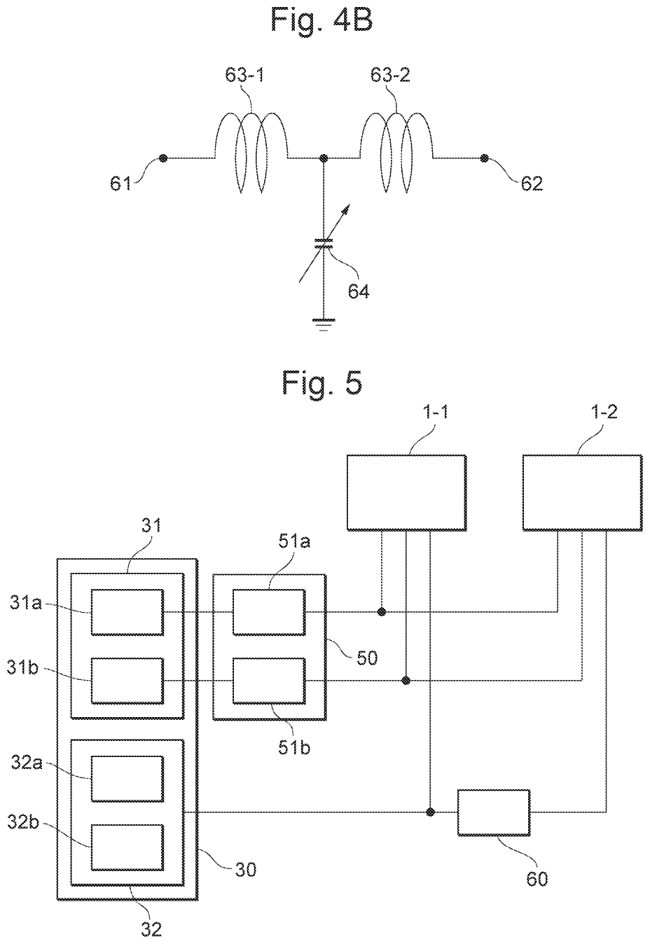

FIG. 4A and FIG. 4B are diagrams illustrating an example of the circuit configuration of the phase control circuit 60. The phase control circuit 60 has an input terminal 61, an output terminal 62, one or more inductors 63, and one or more capacitors 64. The phase control circuit 60 is electrically coupled to the output terminal of the second matching circuit 51b in the input terminal 61. In addition, the phase control circuit 60 is electrically coupled to the lower electrode included in the second plasma processing apparatus 1-2 or to the conductive member functioning as the lower electrode in the output terminal 62. The phase control circuit 60 may be a circuit including a plurality of stages of one or both of two circuits illustrated in FIG. 4A and FIG. 4B in series.

The phase control circuit 60 illustrated in FIG. 4A has one inductor 63 and two capacitors 64-1 and 64-2. One end of the inductor 63 is electrically coupled to the input terminal 61, and the other end of the inductor 63 is electrically coupled to the output terminal 62. One end of the capacitor 64-1 is electrically coupled to the input terminal 61 and to one end of the inductor 63, and the other end of the capacitor 64-1 is grounded. In addition, one end of the capacitor 64-2 is electrically coupled to the output terminal 62 and to the other end of the inductor 63, and the other end of the capacitor 64-2 is grounded.

The phase control circuit 60 illustrated in FIG. 4B has two inductors 63-1 and 63-2 and one capacitor 64. The inductors 63-1 and 63-2 are provided in series between the input terminal 61 and the output terminal 62. That is, one end of the inductor 63-1 is electrically coupled to the input terminal 61, and the other end of the inductor 63-1 is electrically coupled to one end of the inductor 63-2. In addition, the other end of the inductor 63-2 is electrically coupled to the output terminal 62. One end of the capacitor 64 is electrically coupled to the other end of the inductor 63-1 and to one end of the inductor 63-2, and the other end of the capacitor 64 is grounded.

The inductor 63, the capacitor 64, and/or other elements included in the phase control circuit 60 may be configured to have a variable characteristic. The capacitor 64 included in the phase control circuit 60 illustrated in FIG. 4A and FIG. 4B is a variable capacitor having variable capacitance. In addition, the inductor 63 may be a variable inductor having variable inductance. In a case where the phase control circuit 60 includes a variable element such as the variable capacitor and the variable inductor, the controller 2 (refer to FIG. 1) may control the phase difference of the second bias RF signal, generated by the phase control circuit 60, with respect to the first bias RF signal by controlling characteristic of the variable element. For example, the plasma processing system may include a sensor that is electrically coupled between the first RF generator 31a and the first matching circuit 51a, and the controller 2 may control the characteristic of the variable element based on a measurement value of the sensor. For example, the sensor may be a sensor that measures phase differences of a voltage and a current of the source RF signal or a sensor that measures power of a reflected wave of the source RF signal using a directional coupler. In one embodiment, the sensor is configured to monitor a parameter of the source RF signal between the first RF generator 31a and the first matching circuit 51a and output a monitoring result. The sensor may be a VI sensor or a directional coupler. The VI sensor is configured to monitor the phase differences of the voltage and the current of the source RF signal. The directional coupler is configured to monitor the reflected wave of the source RF signal. The phase control circuit 60 is configured to control the variable inductor and/or the variable capacitor based on the monitoring result output by the sensor. The phase control circuit 60 is configured to control the variable inductor and/or the variable capacitor before or after plasma processing in the second plasma processing apparatus 1-2. The phase control circuit 60 may be configured to control the variable inductor and/or the variable capacitor during the plasma processing in the second plasma processing apparatus 1-2.

The exhaust system 40 (refer to FIG. 3) may be connected to, for example, a gas exhaust port 10e provided in a bottom portion of the plasma processing chamber 10. The exhaust system 40 may include a pressure control valve and a vacuum pump. A pressure in the plasma processing space 10s is controlled by the pressure control valve. The vacuum pump may include a turbomolecular pump, a dry pump, or a combination thereof.

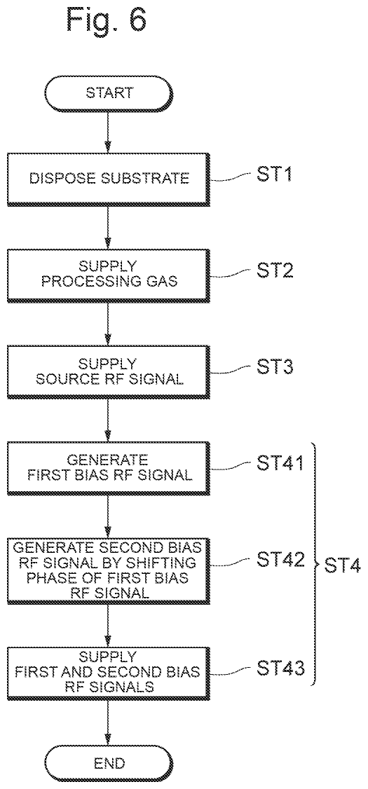

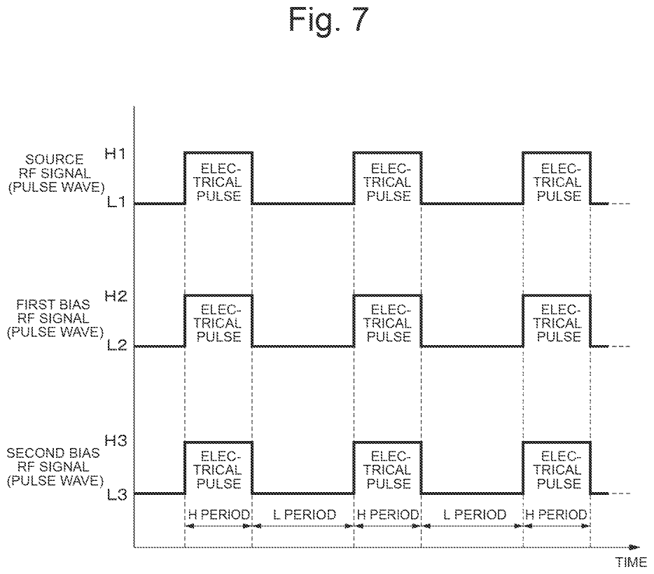

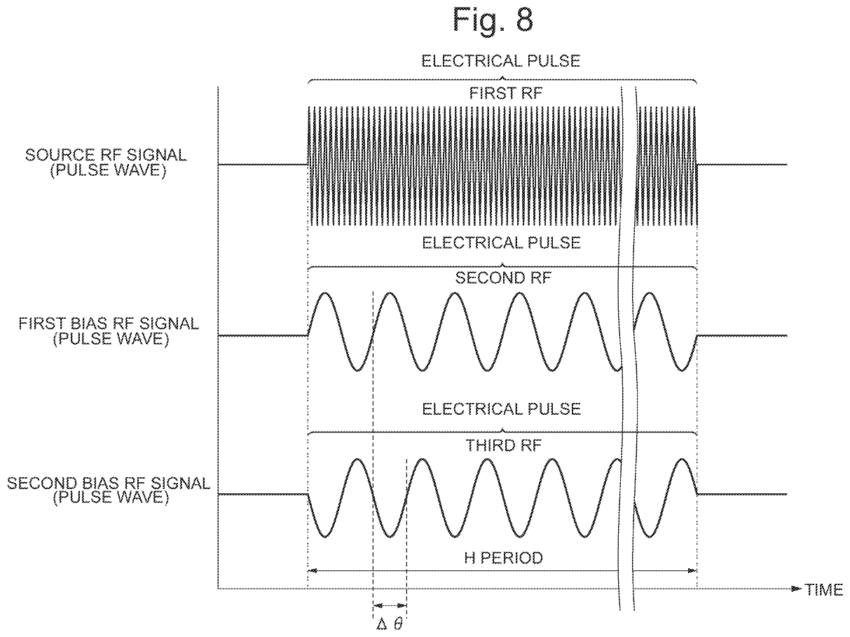

FIG. 6 is a flowchart illustrating a plasma processing method (hereinafter, referred to as the “present processing method”) according to one exemplary embodiment. FIG. 7 and FIG. 8 are timing charts illustrating an example of a period in which the source RF signal, the first bias RF signal, and the second bias RF signal are supplied in the present processing method. In FIG. 7, the horizontal axis denotes time. In addition, in FIG. 7, the vertical axis denotes a power level of each of the source RF signal, the first bias RF signal, and the second bias RF signal (for example, an effective value of power of each of the source RF signal, the first bias RF signal, and the second bias RF signal). Each signal “L1” indicates that each signal is not supplied (that is, the power level is 0 W) or is lower than a power level indicated by “H1”.

As illustrated in FIG. 6, the present processing method includes a step of disposing the substrate (ST1), a step of supplying the processing gas (ST2), a step of supplying the source RF signal (ST3), and a step of supplying the bias RF signal (ST4). In addition, the step of supplying the bias RF signal (ST4) includes a step of generating the first bias RF signal (ST41), a step of supplying the first bias RF signal (ST42), a step of generating the second bias RF signal (ST43), and a step of supplying the second bias RF signal (ST44). While each step of the present processing method will be described below, a description related to the “plasma processing chamber 10” is a description related to both of the first plasma processing apparatus 1-1 and the second plasma processing apparatus 1-2, unless otherwise specified.

In step ST1, the substrate W is disposed on the substrate support 11.

The substrate W may be, for example, a substrate obtained by stacking an underlying film, an etching film etched using the present processing method, a mask film having a predetermined pattern, or the like on a silicon wafer. The etching film may be, for example, a dielectric film, a semiconductor film, or a metal film. In step ST2, the processing gas is supplied into the plasma processing chamber 10. The processing gas is a gas to be used for etching the etching film formed in the substrate W. A type of the processing gas may be appropriately selected based on a material of the etching film, a material of the mask film, a material of the underlying film, the pattern of the mask film, a depth of etching, and the like.

In step ST3 and step ST4, the source RF signal, the first bias RF signal, and the second bias RF signal are supplied to the plasma processing chamber 10. Step ST3 and step ST4 may start at the same time or may start at different timings. In addition, in a case where step ST3 and step ST4 start at different timings, step ST3 and step ST4 may be started in any order. In addition, the first bias RF signal and the second bias RF signal will be collectively referred to as the “bias RF signal”.

In step ST3, first, the first RF generator 31a generates the source RF signal. As illustrated in FIG. 7 and FIG. 8, the source RF signal is, for example, a pulse wave including an electrical pulse in an H period. That is, the source RF signal is a signal that alternatively repeats an L period in which a power level of a first RF constituting the source RF signal is zero and the H period that is a period in which the power level is high. A frequency of the first RF constituting the electrical pulse of the source RF signal is, for example, greater than or equal to 10 MHz and less than or equal to 120 MHZ. In addition, the power level of the first RF may be a power level greater than zero and less than H1 in the L period. In addition, the source RF signal may be a continuous wave instead of a pulse wave. That is, the source RF signal may be a signal in which the first RF continues.

In addition, the first RF generator 31a supplies the generated source RF signal to the first plasma processing apparatus 1-1 and to the second plasma processing apparatus 1-2 through the first matching circuit 51a. For example, the first RF generator 31a supplies the source RF signal to the substrate support 11 of the first plasma processing apparatus 1-1 and supplies the source RF signal to the substrate support 11 of the second plasma processing apparatus 1-2. Accordingly, the plasma is generated by the processing gas supplied into the chamber in both of the first plasma processing apparatus 1-1 and the second plasma processing apparatus 1-2.

In step ST4, the bias RF signal is supplied to the plasma processing chamber 10. First, in step ST41, the second RF generator 31b generates the first bias RF signal. As illustrated in FIG. 7 and FIG. 8, the first bias RF signal is, for example, a pulse wave including an electrical pulse in the H period. That is, the first bias RF signal is a signal that alternatively repeats the L period in which a power level of a second RF constituting the first bias RF signal is zero and the H period that is a period in which the power level is high. The second RF constituting the first bias RF signal has a lower frequency than the first RF constituting the source RF signal. The frequency of the second RF is, for example, greater than or equal to 100 kHz and less than or equal to 20 MHZ. The frequency of the second RF may be greater than or equal to 400 kHz and less than or equal to 4 MHZ. In addition, the bias RF signal may be a continuous wave instead of a pulse wave. That is, the first bias RF signal may be a signal in which the second RF continues. For example, both of the source RF signal and the first bias RF signal (and the second bias RF signal) may be continuous waves. In addition, one may be a continuous wave, and the other may be a pulse wave.

In a case where the first bias RF signal is generated in step ST41, the phase control circuit 60 generates the second bias RF signal in step ST42. The phase control circuit 60 generates the second bias RF signal by receiving the first bias RF signal from the first RF generator 31a and shifting the phase of the first bias RF signal. That is, as illustrated in FIG. 8, in the H period, a third RF constituting the second bias RF signal has a phase difference Δθ with respect to the second RF constituting the electrical pulse of the first bias RF signal. In one embodiment, the phase difference Δθ is 180 degrees.

The phase difference 40 may be set based on a measurement value of a characteristic of a first RF signal. The characteristic may be, for example, phase differences of a voltage and a current of the first RF signal or power of a reflected wave of the first RF signal. For example, the sensor electrically coupled between the first RF generator 31a and the first matching circuit 51a may measure the characteristic of the first RF signal, and the controller 2 may control the characteristic of the variable element included in the phase control circuit 60 based on the measurement value of the characteristic. The controller 2 may set the phase difference 40 in advance before executing the plasma processing (for example, etching processing) with respect to the substrate W. The controller 2 may execute the plasma processing with respect to the substrate W by maintaining the phase difference Δθ to be constant during execution of the plasma processing, by maintaining the characteristic of the variable element included in the phase control circuit 60 to be constant. In addition, the controller 2 may dynamically control the phase difference Δθ during execution of the plasma processing. For example, the sensor electrically coupled between the first RF generator 31a and the first matching circuit 51a may measure the characteristic of the first RF signal during execution of the plasma processing, and the controller 2 may dynamically control the characteristic of the variable element included in the phase control circuit 60 during execution of the plasma processing based on the measurement value of the characteristic.

In a case where the first bias RF signal and the second bias RF signal are generated in step ST41 and step ST42, the first bias RF signal is supplied to the first plasma processing apparatus 1-1, and the second bias RF signal is supplied to the second plasma processing apparatus 1-2 in step ST43. For example, the first bias RF signal and the second bias RF signal are supplied to the bias electrodes included in the substrate supports 11 of the first plasma processing apparatus 1-1 and the second plasma processing apparatus 1-2, respectively. Accordingly, capacitance of a first sheath (hereinafter, referred to as “first sheath capacitance”) generated between the substrate W and the plasma in the first plasma processing apparatus 1-1 changes based on the phase of the first bias RF signal. In addition, capacitance of a second sheath (hereinafter, referred to as “second sheath capacitance”) generated between the substrate W and the plasma in the second plasma processing apparatus 1-2 changes based on a phase of the second bias RF signal.

Accordingly, the plasma processing method executed in the plasma processing system including the first plasma processing apparatus 1-1 and the second plasma processing apparatus 1-2 includes a first step to a sixth step. In the first step, the first RF signal having the first frequency is generated. In the second step, a second RF signal having the second frequency lower than the first frequency is generated. In the third step, a phase of the second RF signal is shifted. In the fourth step, the first RF signal is supplied to the first plasma processing apparatus 1-1 and to the second plasma processing apparatus 1-2. In the fifth step, the second RF signal is supplied to the first plasma processing apparatus 1-1. In the sixth step, the second RF signal of which the phase is shifted is supplied to the second plasma processing apparatus 1-2.

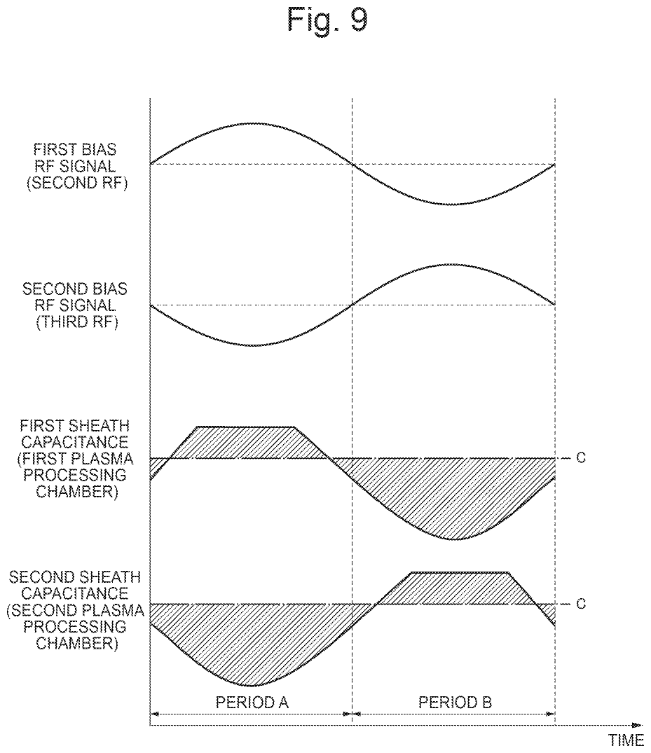

FIG. 9 is a diagram illustrating an example of a relationship between the phase of the bias RF signal and sheath capacitance. In FIG. 9, a waveform diagram of the first bias RF signal is a waveform diagram illustrating one cycle of the second RF included in the first bias RF signal. In addition, a waveform diagram of the second bias RF signal is a waveform diagram illustrating one cycle of the third RF included in the second bias RF signal. A graph of the first sheath capacitance is a graph illustrating the first sheath capacitance with respect to each phase of the first bias RF signal. In addition, a graph of the second sheath capacitance is a graph illustrating the second sheath capacitance with respect to each phase of the second bias RF signal. In the example illustrated in FIG. 9, the phase difference Δθ between the first bias RF signal and the second bias RF signal is 180 degrees.

In the present embodiment, the first matching circuit 51a is configured to cause the impedance of the input terminal and the impedance of the output terminal of the first matching circuit 51a to match in a case where each of the first sheath capacitance and the second sheath capacitance is capacitance C. That is, in a case where the first sheath capacitance and the second sheath capacitance are the capacitance C, impedance of the first plasma processing apparatus 1-1 and the second plasma processing apparatus 1-2 is matching impedance. On the other hand, in a case where the first sheath capacitance and the second sheath capacitance are other than the capacitance C, the impedance of the first plasma processing apparatus 1-1 and the second plasma processing apparatus 1-2 deviates from the matching impedance. That is, impedance mismatching may occur based on a difference between the first sheath capacitance and the second sheath capacitance, and the capacitance C (the hatched part in FIG. 9).

On the other hand, as illustrated in FIG. 9, according to the present embodiment, a phase difference is provided between the first bias RF signal and the second bias RF signal. Thus, in a case where impedance mismatching of one of the first plasma processing apparatus 1-1 and the second plasma processing apparatus 1-2 is increased, impedance mismatching of the other is decreased. Accordingly, even in a case where impedance mismatching of one of the first plasma processing apparatus 1-1 and the second plasma processing apparatus 1-2 is large, the power of the source RF signal is supplied more to the plasma processing chamber of the other having small impedance mismatching. For example, in a period A (a half cycle of the bias RF signal) illustrated in FIG. 9, the second sheath capacitance deviates from the capacitance C more significantly than the first sheath capacitance. Accordingly, in the period A, the power of the source RF signal is supplied more to the first plasma processing apparatus 1-1 than to the second plasma processing apparatus 1-2. In addition, in a period B (a half cycle of the bias RF signal), similarly, the power of the source RF signal is supplied more to the second plasma processing apparatus 1-2 than to the first plasma processing apparatus 1-1. Accordingly, since occurrences of the reflected wave of the source RF signal can be reduced, a loss of the power of the source RF signal can be suppressed. In addition, fluctuations of a load seen from the first RF generator 31a can be reduced.

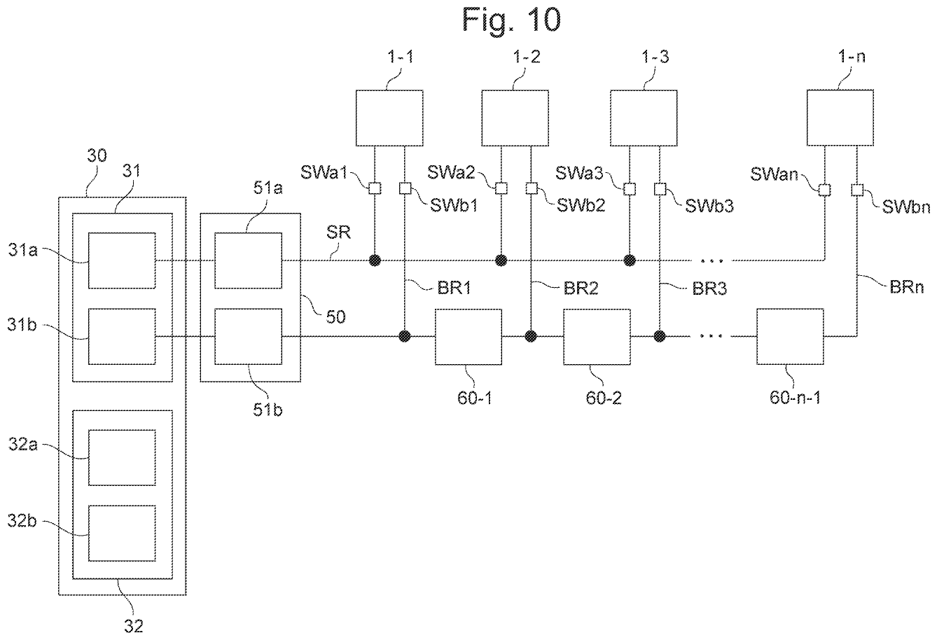

FIG. 10 is a block diagram illustrating an example of a configuration of the plasma processing system according to one exemplary embodiment. The plasma processing system according to the present embodiment includes n plasma processing apparatuses, that is, plasma processing apparatuses 1-1 to 1-n. Here, n is an integer greater than or equal to 2. In addition, the plasma processing system includes the power supply 30, the impedance matching circuit 50, and (n−1) phase control circuits 60-1 to 60-n−1. In one embodiment, each of the plasma processing apparatuses 1-1 to 1-n may have the same configuration as the plasma processing apparatus 1 illustrated in FIG. 3.

The first matching circuit 51a is coupled to the first RF generator 31a. In addition, the plasma processing apparatuses 1-1 to 1-n are coupled in parallel to the first matching circuit 51a. Specifically, each of one or more upper electrodes or each of one or more lower electrodes disposed in the plasma processing apparatuses 1-1 to 1-n is coupled to the first matching circuit 51a. Accordingly, a source RF signal SR generated in the first RF generator 31a is supplied to one or more upper electrodes or one or more lower electrodes of the plasma processing apparatuses 1-1 to 1-n through the first matching circuit 51a.

The second matching circuit 51b is coupled to the second RF generator 31b. In addition, the plasma processing apparatuses 1-1 to 1-n are coupled in parallel to the second matching circuit 51b. Specifically, each of one or more lower electrodes disposed in the plasma processing apparatuses 1-1 to 1-n is coupled to the second matching circuit 51b. Accordingly, the bias RF signal generated in the second RF generator 31b is supplied to one or more lower electrodes of the plasma processing apparatuses 1-1 to 1-n through the second matching circuit 51b. The phase control circuits 60-1 to 60-n−1 are coupled in series between the second matching circuit 51b and the plasma processing apparatus 1-n. Specifically, the phase control circuit 60-1 is coupled to the second matching circuit 51b and to the phase control circuit 60-2. In addition, the phase control circuit 60-2 is coupled to the phase control circuit 60-1 and to the phase control circuit 60-3. In addition, the phase control circuit 60-n−1 is coupled to the phase control circuit 60-n−2 and to the plasma processing apparatus 1-n.

The k-th phase control circuit 60-k among the phase control circuits 60-1 to 60-n−1 is coupled to the k-th plasma processing apparatus 1-k and to the (k+1)-th plasma processing apparatus 1-k+1 among the plasma processing apparatuses 1-1 to 1-n (k is an integer of 1 to n−1). Specifically, the plasma processing apparatus 1-k is coupled to the input terminal of the phase control circuit 60-k, and the plasma processing apparatus 1-k+1 is coupled to the output terminal of the phase control circuit 60-k.

The phase control circuits 60-1 to 60-n−1 receive the bias RF signal generated in the second RF generator 31b through the second matching circuit 51b and sequentially shift the phase of the bias RF signal (hereinafter, the bias signal generated in the second RF generator 31b will be referred to as a “bias RF signal BR1”, and the bias RF signal of which the phase is shifted by the phase control circuit 60-k will be referred to as a “bias RF signal BRk+1”; in addition, the bias RF signals BR1 to BRn will be collectively referred to as the “bias RF signal”; in addition, one of the bias RF signals BR1 to BRn will be referred to as the “bias RF signal”). In addition, the bias RF signal BRk is supplied to the plasma processing apparatus 1-k. For example, the bias RF signal BR1 generated in the second RF generator 31b is supplied to the plasma processing apparatus 1-1 and to the phase control circuit 60-1 through the second matching circuit 51b. In addition, the phase control circuit 60-1 generates the bias RF signal BR2 by shifting the phase of the bias RF signal BR1. The bias RF signal BR2 is supplied to the plasma processing apparatus 1-2 and to the phase control circuit 60-2. The phase control circuit 60-n−1 generates the bias RF signal BRn by shifting the phase of the bias RF signal BRn−1. The bias RF signal BRn is supplied to the plasma processing apparatus 1-n. Each of the phase control circuits 60-1 to 60-n−1 may have the same configuration and/or function as the phase control circuit 60 described in FIG. 4A and FIG. 4B.

In the present embodiment, the plasma processing system has switches SWa1 to SWan and switches SWb1 to SWbn. The switches SWa1 to SWan are coupled to the first matching circuit 51a and to the plasma processing apparatuses 1-1 to 1-n. The switches SWa1 to SWan switch whether or not the source RF signal SR generated in the first RF generator 31a is supplied to the plasma processing apparatuses 1-1 to 1-n, respectively. In addition, the switches SWb1 to SWbn are coupled to the second matching circuit 51b or the phase control circuits 60-1 to 60-n−1 and to the plasma processing apparatuses 1-1 to 1-n. The switches SWb1 to SWbn switch whether or not the bias RF signals BR1 to BRn are supplied to the plasma processing apparatuses 1-1 to 1-n, respectively.

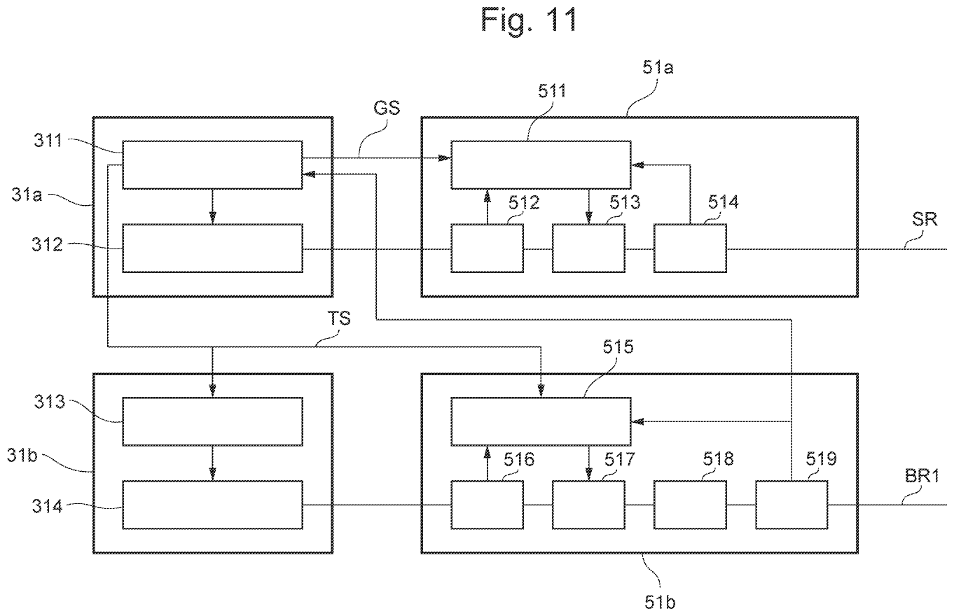

FIG. 11 is a block diagram illustrating an example of configurations of the first RF generator 31a, the second RF generator 31b, the first matching circuit 51a, and the second matching circuit 51b. The first RF generator 31a has a control circuit 311 and an amplification circuit 312. The second RF generator 31b has a control circuit 313 and an amplification circuit 314. The first matching circuit 51a has a control circuit 511, a VI sensor 512, a matching circuit 513, and a voltage sensor 514. The second matching circuit 51b has a control circuit 515, a VI sensor 516, a matching circuit 517, a low-pass filter 518, and a voltage sensor 519.

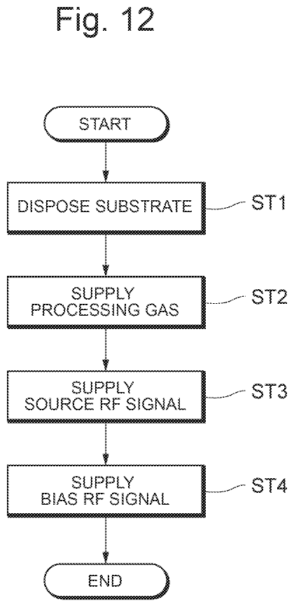

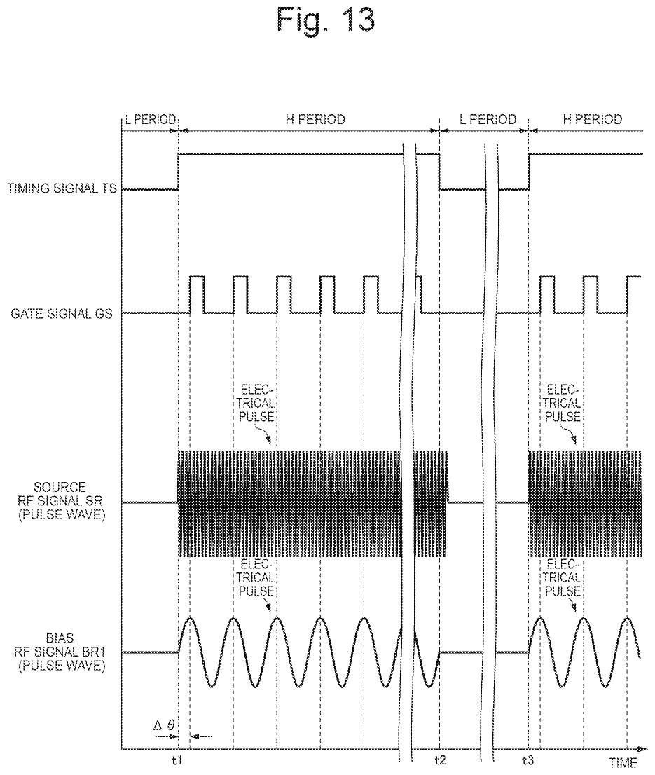

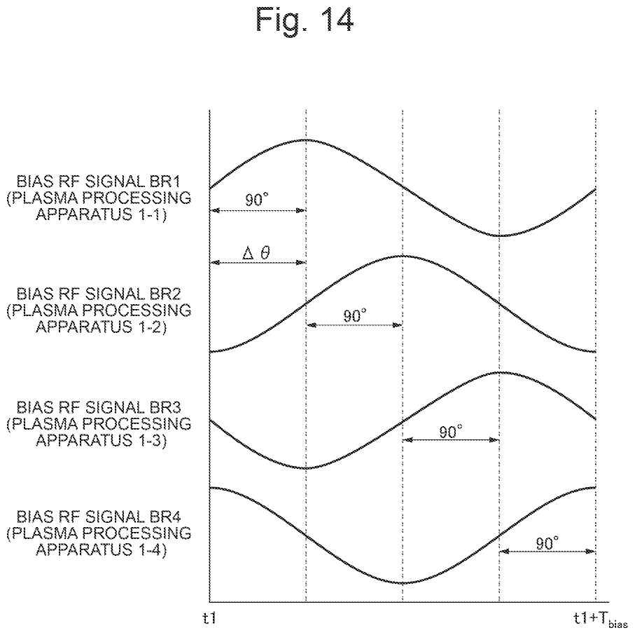

FIG. 12 is a flowchart illustrating an example of the plasma processing method (hereinafter, referred to as the “present processing method”) according to the present embodiment. FIG. 13 is a timing chart illustrating an example of a period in which the source RF signal SR and the bias RF signal BR1 are supplied in the present processing method. FIG. 14 is a timing chart illustrating an example of the phase of each bias RF signal. Hereinafter, an example of the present processing method will be described with reference to FIG. 10 to FIG. 14.

As illustrated in FIG. 12, the present processing method includes a step of disposing the substrate (ST1), a step of supplying the processing gas (ST2), a step of generating the source RF signal (ST3), and a step of generating the bias RF signal (ST4). In addition, a part or all of steps T included in the present processing method may be executed in parallel in the plasma processing apparatuses 1-1 to 1-n. In the example illustrated in FIG. 12, at least step ST3 and step ST4 may be executed in parallel in the plasma processing apparatuses 1-1 to 1-n. In addition, in the present processing method, step ST2 to step ST4 may be executed at the same time. In addition, step ST2 to step ST4 may be executed in a different order from an order described below.

First, in step ST1, the substrate W is disposed on the substrate support 11 in each of the plasma processing apparatuses 1-1 to 1-n. In step ST2, the processing gas is supplied to the plasma processing chamber 10.

Next, in step ST3, the first RF generator 31a generates the source RF signal SR. As illustrated in FIG. 13, the source RF signal SR is a pulse wave including an electrical pulse in the H period. For example, the source RF signal SR is generated as follows. That is, first, in the first RF generator 31a, the control circuit 311 generates a timing signal TS (refer to FIG. 11 and FIG. 13). The timing signal TS is a signal indicating the H period and the L period of the source RF signal and/or the bias RF signal. That is, the timing signal TS is a signal having a period in which a voltage of the timing signal TS is high (hereinafter, referred to as “ON”) and a period in which the voltage of the timing signal TS is low (hereinafter, referred to as “OFF”). In the period in which the timing signal TS is ON, the source RF signal and/or the bias RF signal is in the H period. In addition, in the period in which the timing signal TS is OFF, the source RF signal and/or the bias RF signal is in the L period.

As illustrated in FIG. 13, at time t1, in a case where the timing signal TS changes to ON from OFF, the amplification circuit 312 generates an RF.

Accordingly, as illustrated in FIG. 13, an electrical pulse is generated in the source RF signal SR at time t1. By periodically generating electrical pulses based on the timing signal TS via the amplification circuit 312, the source RF signal SR is generated. The generated source RF signal SR is supplied to the first matching circuit 51a.

Next, in step ST4, the second RF generator 31b generates the bias RF signal BR1. The bias RF signal BR1 is generated based on the timing signal TS generated by the control circuit 311 of the first RF generator 31a. That is, first, the control circuit 311 supplies the timing signal TS to the control circuit 313 of the second RF generator 31b. In a case where the timing signal TS is ON at time t1, the amplification circuit 314 generates an RF based on an instruction from the control circuit 313. Accordingly, as illustrated in FIG. 13, an electrical pulse is generated in the bias RF signal BR1 at time t1. By periodically generating electrical pulses based on the timing signal TS via the amplification circuit 314, the bias RF signal BR1 is generated. The generated bias RF signal BR1 is supplied to the second matching circuit 51b.

In a case where the bias RF signal BR1 is supplied to the second matching circuit 51b, the second matching circuit 51b causes the impedance of the input terminal (hereinafter, referred to as “input impedance”) and the impedance of the output terminal (hereinafter, referred to as “output impedance”) of the second matching circuit 51b to match. Specifically, first, the VI sensor 516 measures the voltage and the current of the bias RF signal BR1 supplied from the second RF generator 31b. The control circuit 515 causes the input impedance and the output impedance of the second matching circuit 51b to match by controlling the matching circuit 517 based on the measured voltage and the measured current.

The bias RF signal BR1 is supplied to the plasma processing apparatus 1-1 and to the phase control circuit 60-1 by passing through the matching circuit 51b and then passing through the low-pass filter 518. In addition, in the second matching circuit 51b, the voltage sensor 519 measures the voltage of the bias RF signal BR1 that has passed through the low-pass filter. The voltage measured in the voltage sensor 519 is supplied to the control circuit 515 and to the control circuit 311 of the first RF generator 31a.

In a case where the voltage measured in the voltage sensor 519 is supplied to the control circuit 311, the control circuit 311 generates a gate signal GS based on the voltage. For example, as illustrated in FIG. 13, the control circuit 311 may generate a pulse in the gate signal GS at a timing at which the voltage of the bias RF signal BR1 has a peak. That is, the gate signal GS may be a signal that periodically includes pulses and that has each pulse appearing at the timing at which the voltage of the bias RF signal BR1 has the peak. In addition, the control circuit 311 supplies the generated gate signal GS to the control circuit 511 of the first matching circuit 51a.

In addition, the first matching circuit 51a causes the input impedance and the output impedance of the first matching circuit 51a to match based on the gate signal GS. The input impedance may include the output impedance of the first RF generator 31a. In addition, the output impedance of the first matching circuit 51a may include impedance of loads of the plasma processing apparatuses 1-1 to 1-n. For example, the first matching circuit 51a causes the input impedance and the output impedance to match at a timing at which a pulse appears in the gate signal GS. For example, the input impedance and the output impedance of the first matching circuit 51a may be caused to match by controlling the matching circuit 513 based on the voltage and the current of the source RF signal SR measured by the VI sensor 512 at the timing at which the pulse appears in the gate signal GS. That is, the first matching circuit 51a may cause the input impedance and the output impedance of the first matching circuit 51a to match at the timing at which the voltage of the bias RF signal BR1 has the peak.

The bias RF signal BR1 output from the second matching circuit 51b is supplied to the plasma processing apparatus 1-1 and to the phase control circuit 60-1. The phase control circuit 60-1 generates the bias RF signal BR2 by shifting the phase of the bias RF signal BR1. In addition, the phase control circuit 60-1 supplies the bias RF signal BR2 to the plasma processing apparatus 1-2 and to the phase control circuit 60-2. The phase control circuits 60-2 to 60-n−1 generate the bias RF signals BR3 to BRn, respectively, by sequentially shifting the phases of the received bias RF signals BR2 to BRn−1. Each of the phase control circuits 60-1 to 60-n−1 shifts the phase of the received bias RF signal based on the number n of plasma processing apparatuses 1. In the present example, the phase control circuits 60-1 to 60-n−1 shift the phase of the received bias RF signal by 360°/n, that is, an angle obtained by dividing 360° by the number of plasma processing apparatuses 1. In addition, the phase control circuits 60-2 to 60-n−1 supply the bias RF signals BR3 to BRn to the plasma processing apparatuses 1-3 to 1-n, respectively. In addition, the phase control circuits 60-2 to 60-n−2 supply the bias RF signals BR3 to BRn−1 to the phase control circuits 60-3 to 60-n−1.

FIG. 14 is a timing chart illustrating an example of the phases of the bias RF signals BR1 to BR4 in one cycle of the bias RF signal BR1. In FIG. 14, an example of n=4, that is, an example in which the plasma processing apparatuses 1-1 to 1-4 are coupled to the first matching circuit 51a, is illustrated. That is, in the example in FIG. 14, the phase control circuits 60-1 to 60-3 are coupled in series between the second matching circuit 51b and the plasma processing apparatus 1-4. In FIG. 14, the horizontal axis denotes time or the phase. Tbias is one cycle of the bias RF signal BR1.

As illustrated in FIG. 14, the phase of the bias RF signal BR2 is shifted by 360°/4, that is, 90°, with respect to the bias RF signal BR1. Similarly, the phase of the bias RF signal BR3 is shifted by 90° with respect to the bias RF signal BR2. In addition, the phase of the bias RF signal BR4 is shifted by 90° with respect to the bias RF signal BR3. In the present example, the first matching circuit 51a causes the impedance to match at a timing of a delay of Δθ in phase from time t1, that is, a timing at which the phase of the bias RF signal BR1 is 90°. Then, as described in FIG. 9, the impedance mismatching seen from the first matching circuit 51a is the largest in the plasma processing apparatus 1-3, is the second largest in the plasma processing apparatuses 1-2 and 1-4, and is the smallest in the plasma processing apparatus 1-1. Then, the power of the source RF signal SR is supplied more to the plasma processing apparatus 1-1. In a case where the phase further advances by 90°, the impedance mismatching is the smallest in the plasma processing apparatus 1-2, and the power of the source RF signal SR is supplied more to the plasma processing apparatus 1-2. In addition, in a case where the phase further advances by 90°, the impedance mismatching is the smallest in the plasma processing apparatus 1-3, and the power of the source RF signal SR is supplied more to the plasma processing apparatus 1-3. In addition, in a case where the phase further advances by 90°, the impedance mismatching is the smallest in the plasma processing apparatus 1-4, and the power of the source RF signal SR is supplied more to the plasma processing apparatus 1-4. That is, the power of the source RF signal SR is supplied more to any of the plasma processing apparatuses 1-1 to 1-4 over one cycle of the bias RF signal. Accordingly, since occurrences of reflection of the source RF signal SR can be reduced, a loss of the power of the source RF signal SR can be suppressed.

A timing at which the first matching circuit 51a performs impedance matching is not limited to the peak of the voltage of the bias RF signal BR1. For example, the timing may be any timing in the period A illustrated in FIG. 9. In addition, the timing may be a plurality of timings in the period A illustrated in FIG. 9. In addition, the timing may be a timing at which the impedance of the plasma processing apparatus 1-1 to 1-n does not overlap with each other. For example, in the case of n=4, the timing may be a timing at which the phases of the bias RF signals BR1 to BR4 are 30° and 150°.

In addition, the plasma processing system may be operated by separating one or more of the plasma processing apparatuses 1-1 to 1-n from the impedance matching circuit 50 using the switches SWa1 to SWan and the switches SWb1 to SWbn. The one or more plasma processing apparatuses may be, for example, a plasma processing apparatus in a down state or in an idle state. In this case, the phase control circuits 60-1 to 60-n−1 may control a shift amount of the phase in accordance with the number of plasma processing apparatuses coupled to the impedance matching circuit 50. For example, in the example illustrated in FIG. 14, in a case where the plasma processing apparatus 1-4 is in the down state or in the idle state, the phase control circuits 60-1 and 60-2 may shift the phase by 360°/3, that is, 120°, based on n=3.

With reference to FIG. 13, at time t2, in a case where the timing signal TS changes to OFF from ON, the first RF generator 31a and the second RF generator 31b stop generating the source RF signal SR and a bias DC signal BD1. At time t3, in a case where the timing signal TS changes to ON from OFF, the first RF generator 31a and the second RF generator 31b start generating the source RF signal SR and the bias DC signal BD1 again. By repeating the above operation, the plasma is generated from the processing gas in the plasma processing chamber 10, and the plasma processing (for example, the etching processing) is executed with respect to the substrate W.

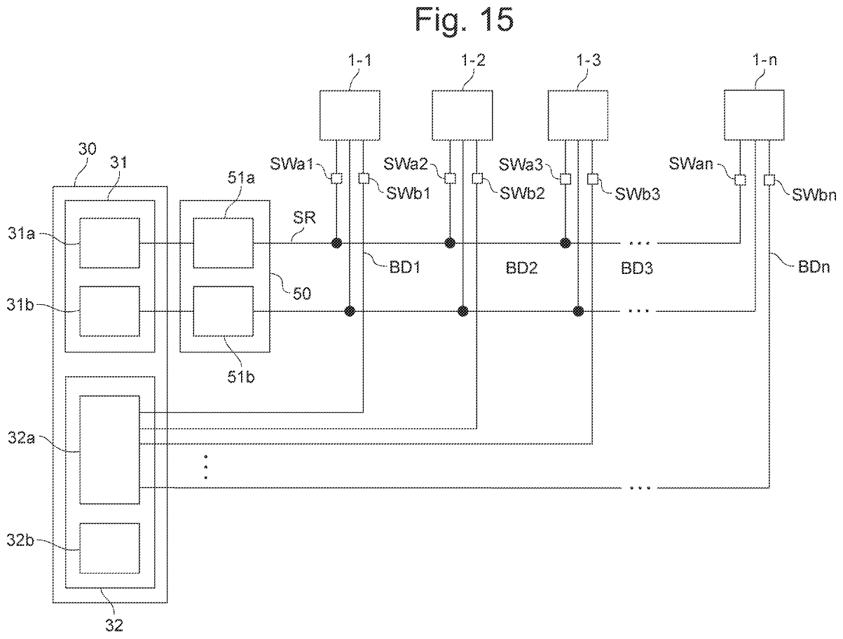

FIG. 15 is a block diagram illustrating an example of a configuration of the plasma processing system according to one exemplary embodiment. The plasma processing system according to the present embodiment is mainly different from the plasma processing system illustrated in FIG. 10 in that a bias DC signal is supplied to the plasma processing apparatuses 1-1 to 1-n as the bias signal. That is, in the present embodiment, the first DC generator 32a generates bias DC signals BD1 to BDn, and the bias DC signals BD1 to BDn are supplied to the plasma processing apparatuses 1-1 to 1-n.

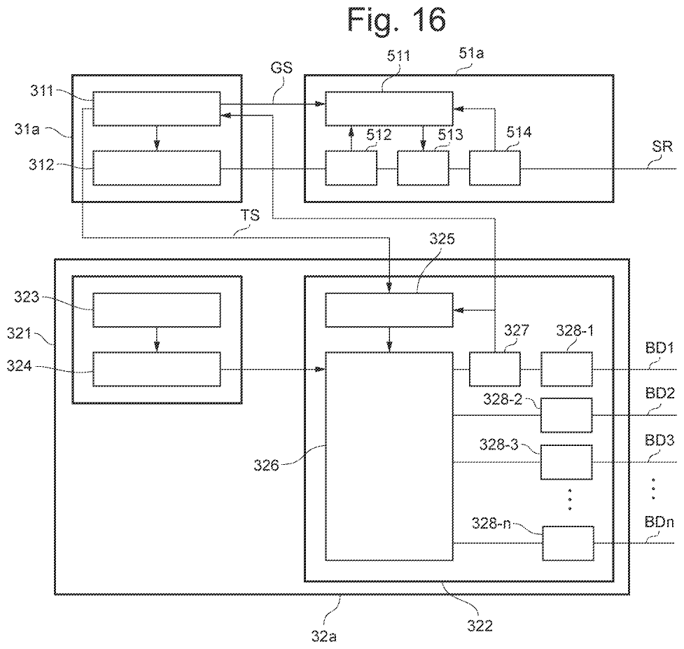

FIG. 16 is a block diagram illustrating an example of configurations of the first RF generator 31a, the first DC generator 32a, and the first matching circuit 51a. The first DC generator 32a has a DC generator 321 and a DC controller 322. The DC generator 321 has a control circuit 323 and an amplification circuit 324. The DC controller 322 has a control circuit 325, a pulse generation circuit 326, a voltage sensor 327, and low-pass filters 328-1 to 328-n.

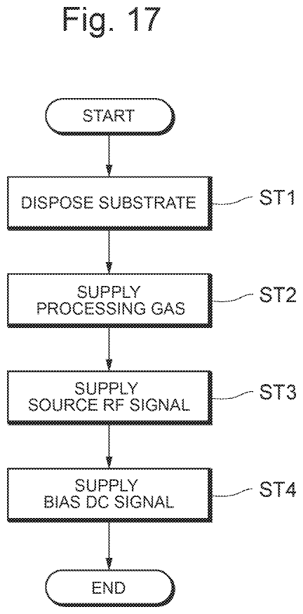

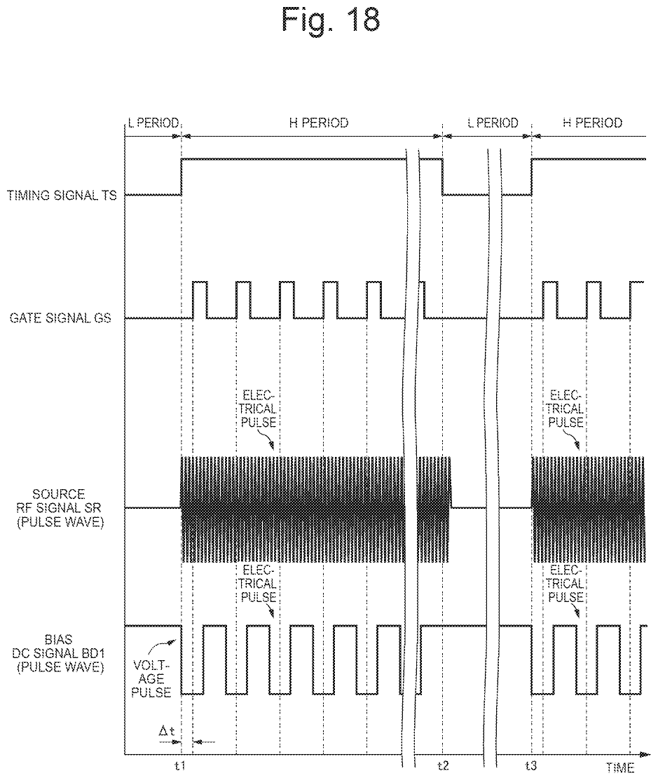

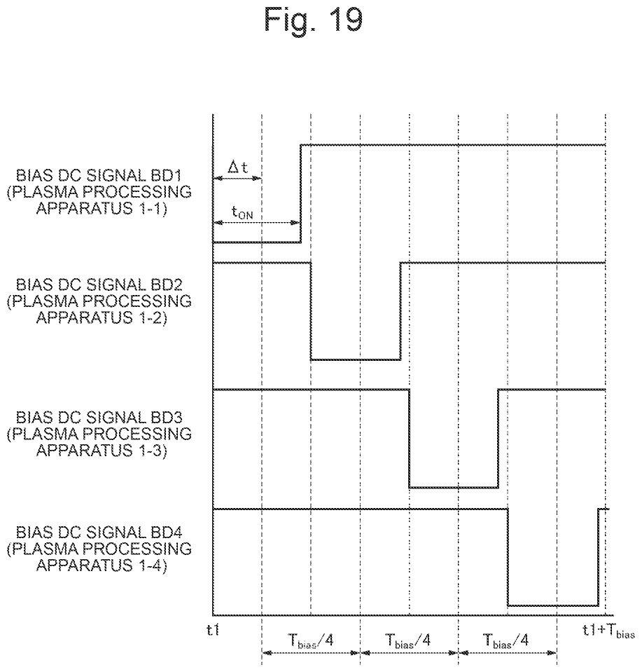

FIG. 17 is a flowchart illustrating an example of the plasma processing method (hereinafter, referred to as the “present processing method”) according to the present embodiment. FIG. 18 is a timing chart illustrating an example of a period in which the source RF signal SR and the bias DC signal BD1 are supplied in the present processing method. FIG. 19 is a timing chart illustrating an example of a phase of each bias DC signal. Hereinafter, an example of the present processing method will be described with reference to FIG. 15 to FIG. 19.

As illustrated in FIG. 17, the present processing method includes a step of disposing the substrate (ST1), a step of supplying the processing gas (ST2), a step of generating the source RF signal (ST3), and a step of generating the bias DC signal (ST4). A part or all of the steps T included in the present processing method may be executed in parallel in the plasma processing apparatuses 1-1 to 1-n. In the example illustrated in FIG. 17, at least step ST3 and step ST4 may be executed in parallel in the plasma processing apparatuses 1-1 to 1-n. In addition, in the present processing method, step ST2 to step ST4 may be executed at the same time. In addition, step ST2 to step ST4 may be executed in a different order from an order described below.

First, in step ST1, the substrate W is disposed on the substrate support 11 in each of the plasma processing apparatuses 1-1 to 1-n. In step ST2, the processing gas is supplied to the plasma processing chamber 10.

Next, in step ST3, the first RF generator 31a generates the source RF signal SR. As illustrated in FIG. 18, at time t1, in a case where the timing signal TS changes to ON from OFF, the source RF signal SR is generated. The generated source RF signal SR is supplied to the first matching circuit 51a.

Next, in step ST4, the first DC generator 32a generates the bias DC signal BD1. The bias DC signal BD1 is generated based on the timing signal TS. That is, first, the control circuit 311 of the first RF generator 31a supplies the timing signal TS to the control circuit 313 of the DC controller 322. In a case where the timing signal TS is ON at time t1, the pulse generation circuit 326 generates the sequence of voltage pulses from a DC voltage generated in the DC generator 321. The generated sequence of voltage pulses passes through the low-pass filter 328-1 and is output from the first DC generator 32a as the bias DC signal BD1. In addition, in the DC controller 322, the voltage sensor 327 generates a voltage of the sequence of voltage pulses generated by the pulse generation circuit 326. The voltage measured by the voltage sensor 327 is supplied to the control circuit 325 and to the control circuit 311 of the first RF generator 31a.

In a case where the voltage measured in the voltage sensor 327 is supplied to the control circuit 311, the control circuit 311 generates the gate signal GS based on the voltage. For example, as illustrated in FIG. 18, the control circuit 311 may generate a pulse in the gate signal GS at a timing at which a voltage value of the voltage pulse is substantially constant. The timing at which the pulse appears in the gate signal GS may be around a half value of a pulse width of the voltage pulse. The first matching circuit 51a causes the input impedance and the output impedance of the first matching circuit 51a to match based on the gate signal GS.

The pulse generation circuit 326 generates the bias DC signals BD2 to BDn of which the phases are shifted with respect to the bias DC signal BD1. The bias DC signals BD2 to BDn include the sequence of voltage pulses like the bias DC signal BD1. The pulse generation circuit 326 shifts the phases of the bias DC signals BD2 to BDn based on the number n of plasma processing apparatuses 1. In the present example, the pulse generation circuit 326 shifts each of the phases of the bias DC signals BD1 to BDn by Tbias/n, that is, a time obtained by dividing one cycle of the bias DC signals BD1 to BDn by the number of plasma processing apparatuses 1.

FIG. 19 is a timing chart illustrating an example of the phases of the bias DC signals BD1 to BD4 in one cycle of the bias DC signal BD1. In FIG. 19, an example of n=4, that is, an example in which the plasma processing apparatuses 1-1 to 1-4 are coupled to the first matching circuit 51a, is illustrated. In FIG. 19, the horizontal axis denotes time or the phase. Tbias is one cycle of the bias DC signal BD1.

As illustrated in FIG. 19, the phase of the bias DC signal BD2 is shifted by Tbias/4, that is, a ¼ cycle, with respect to the bias DC signal BD1. Similarly, the phase of the bias DC signal BD3 is shifted by a ¼ cycle with respect to the bias DC signal BD2. In addition, the phase of the bias DC signal BD4 is shifted by a ¼ cycle with respect to the bias DC signal BD3. In the present example, the first matching circuit 51a causes the impedance to match at a timing of a delay of Δt, that is, Tbias/8, from time t1. At timings at which the voltage pulses of the bias DC signals BD1 to BDn are ON, the impedance mismatching seen from the first matching circuit 51a is the smallest in the plasma processing apparatus to which the voltage pulses are supplied. For example, at a timing at which the voltage pulse of the bias DC signal BD1 is ON, the impedance mismatching seen from the first matching circuit 51a is the smallest in the plasma processing apparatus 1-1, and the power of the source RF signal SR is supplied more to the plasma processing apparatus 1-1. Accordingly, the power of the source RF signal SR is supplied more to any of the plasma processing apparatuses 1-1 to 1-4 over one cycle of the bias DC signal. Accordingly, since occurrences of reflection of the source RF signal SR can be reduced, a loss of the power of the source RF signal SR can be suppressed. The voltage pulses included in each of the bias DC signals BD1 to BDn may be generated not to overlap with each other in time. For example, as illustrated in FIG. 19, tON that is a period in which the voltage pulse is ON may be shorter than Tbias/n.

The embodiments disclosed here are to be considered as being illustrative and non-restrictive in every point. The above embodiments may be omitted, replaced, or changed in various forms without departing from the accompanying claims and the gist of the claims. For example, while the capacitively coupled plasma apparatus has been illustratively described in the above embodiments, the present disclosure is not limited to the capacitively coupled plasma apparatus and may be applied to other plasma apparatuses. For example, an inductively coupled plasma (ICP) apparatus may be used instead of the capacitively coupled plasma apparatus. In this case, the inductively coupled plasma apparatus includes an antenna and a lower electrode. The antenna is disposed in an upper portion of the plasma processing chamber or above the plasma processing chamber, and the lower electrode is disposed in the substrate support. In one embodiment, the first plasma processing apparatus includes the first plasma processing chamber, the first substrate support disposed in the first plasma processing chamber, the first lower electrode disposed in the first substrate support, and a first antenna disposed above the first plasma processing chamber. In addition, the second plasma processing apparatus includes the second plasma processing chamber, the second substrate support disposed in the second plasma processing chamber, the second lower electrode disposed in the second substrate support, and a second antenna disposed above the second plasma processing chamber. The first matching circuit is coupled to the first antenna and to the second antenna. The second matching circuit is coupled to the first lower electrode. The phase control circuit is coupled to the second lower electrode. Accordingly, the first plasma processing apparatus is coupled to the first matching circuit and to the second matching circuit, and the second plasma processing apparatus is coupled to the first matching circuit and to the phase control circuit.

According to one exemplary embodiment of the present disclosure, a plasma processing system that can reduce a reflected wave of an RF signal can be provided.

In addition, the embodiments of the present disclosure may include the following aspects.

(Addendum 1)

A plasma processing system comprising:
a source RF signal generator configured to generate a source RF signal for plasma generation;
a first matching circuit coupled to the source RF signal generator;
a bias RF signal generator configured to generate a bias RF signal;
a second matching circuit coupled to the bias RF signal generator;
a phase control circuit coupled to the second matching circuit and configured to shift a phase of the bias RF signal supplied from the bias RF signal generator through the second matching circuit;
a first plasma processing apparatus including a first plasma processing chamber and a first substrate support, the first substrate support being disposed in the first plasma processing chamber and including one or a plurality of first lower electrodes, the source RF signal being supplied to the first plasma processing apparatus through the first matching circuit, and the bias RF signal being supplied to at least one of the one or the plurality of first lower electrodes of the first plasma processing apparatus through the second matching circuit; and
a second plasma processing apparatus including a second plasma processing chamber and a second substrate support, the second substrate support being disposed in the second plasma processing chamber and including one or a plurality of second lower electrodes, the source RF signal being supplied to the second plasma processing apparatus through the first matching circuit, and the bias RF signal of which the phase is shifted in the phase control circuit being supplied to at least one of the one or the plurality of second lower electrodes of the second plasma processing apparatus.

(Addendum 2)

The plasma processing system according to Addendum 1,
wherein the phase control circuit includes at least one inductor and at least one capacitor.

(Addendum 3)

The plasma processing system according to Addendum 2,
wherein the phase control circuit includes at least one of a variable inductor or a variable capacitor.

(Addendum 4)

The plasma processing system according to Addendum 3, further comprising:
a sensor configured to monitor the source RF signal between the source RF signal generator and the first matching circuit and output a monitoring result,
wherein the phase control circuit is configured to control one or both of inductance of the variable inductor and capacitance of the variable capacitor based on the monitoring result.

(Addendum 5)

The plasma processing system according to Addendum 4,
wherein the sensor is a VI sensor configured to monitor a phase difference of a voltage and a current of the source RF signal.

(Addendum 6)

The plasma processing system according to Addendum 4,
wherein the sensor is a directional coupler configured to monitor a reflected wave of the source RF signal.

(Addendum 7)

The plasma processing system according to any one of Addenda 3 to 6,
wherein the phase control circuit is configured to control one or both of inductance of the variable inductor and capacitance of the variable capacitor before or after plasma processing in the second plasma processing apparatus.

(Addendum 8)

The plasma processing system according to any one of Addenda 3 to 6,
wherein the phase control circuit is configured to control inductance of the variable inductor and capacitance of the variable capacitor during plasma processing in the second plasma processing apparatus.

(Addendum 9)

The plasma processing system according to any one of Addenda 1 to 8,
wherein a phase difference between the bias RF signal and the bias RF signal of which the phase is shifted is 180 degrees.

(Addendum 10)

The plasma processing system according to any one of Addenda 1 to 9,
wherein the first plasma processing apparatus includes a first upper electrode disposed above the first substrate support,
the second plasma processing apparatus includes a second upper electrode disposed above the second substrate support,
the first matching circuit is coupled to at least one of the one or the plurality of first lower electrodes or the first upper electrode and to at least one of the one or the plurality of second lower electrodes or the second upper electrode,
the second matching circuit is coupled to at least one of the one or the plurality of first lower electrodes, and
the phase control circuit is coupled to at least one of the one or the plurality of second lower electrodes.

(Addendum 11)

The plasma processing system according to any one of Addenda 1 to 9,
wherein the first plasma processing apparatus includes a first antenna disposed above the first plasma processing chamber,
the second plasma processing apparatus includes a second antenna disposed above the second plasma processing chamber,
the first matching circuit is coupled to the first antenna and to the second antenna,
the second matching circuit is coupled to at least one of the one or the plurality of first lower electrodes, and
the phase control circuit is coupled to at least one of the one or the plurality of second lower electrodes.

(Addendum 12)

The plasma processing system according to any one of Addenda 1 to 11,
wherein the source RF signal has a frequency within a range of 10 MHz to 120 MHz.

(Addendum 13)

The plasma processing system according to any one of Addenda 1 to 11,
wherein the bias RF signal has a frequency within a range of 100 kHz to 20 MHz.

(Addendum 14)

The plasma processing system according to any one of Addenda 1 to 11,
wherein the bias RF signal has a frequency within a range of 400 kHz to 4 MHz.

(Addendum 15)

The plasma processing system according to any one of Addenda 1 to 14,
wherein the source RF signal is a continuous wave having a first frequency.

(Addendum 16)

The plasma processing system according to any one of Addenda 1 to 14,
wherein the source RF signal is a pulse wave periodically including a plurality of first electrical pulses, and each of the plurality of first electrical pulses includes a continuous wave having a first frequency.

(Addendum 17)

The plasma processing system according to any one of Addenda 1 to 16,
wherein the bias RF signal is a continuous wave having a second frequency.

(Addendum 18)

The plasma processing system according to any one of Addenda 1 to 16,
wherein the bias RF signal is a pulse wave periodically including a plurality of second electrical pulses, and
each of the plurality of second electrical pulses includes a continuous wave having a second frequency.

(Addendum 19)

A plasma processing method executed in a plasma processing system including a first plasma processing apparatus and a second plasma processing apparatus, the plasma processing method comprising:

generating a first RF signal having a first frequency,
generating a second RF signal having a second frequency lower than the first frequency,
shifting a phase of the second RF signal,
supplying the first RF signal to the first plasma processing apparatus and to the second plasma processing apparatus,
supplying the second RF signal to the first plasma processing apparatus, and
supplying the second RF signal of which the phase is shifted to the second plasma processing apparatus.

(Addendum 20)

A plasma processing system comprising:
an RF signal generator configured to generate an RF signal;
a matching circuit coupled to the RF signal generator;
a voltage pulse generator configured to generate a sequence of voltage pulses;
a phase control circuit configured to shift phases of the sequence of voltage pulses supplied from the voltage pulse generator;

a first plasma processing apparatus including a first plasma processing chamber and a first substrate support, the first substrate support being disposed in the first plasma processing chamber and including one or a plurality of first lower electrodes, the RF signal being supplied to the first plasma processing apparatus through the matching circuit, and the sequence of voltage pulses being supplied to the one or the plurality of first lower electrodes of the first plasma processing apparatus from the voltage pulse generator; and
a second plasma processing apparatus including a second plasma processing chamber and a second substrate support, the second substrate support being disposed in the second plasma processing chamber and including one or a plurality of second lower electrodes, the RF signal being supplied to the second plasma processing apparatus through the matching circuit, and the sequence of voltage pulses of which the phases are shifted in the phase control circuit being supplied to at least one of the one or the plurality of second lower electrodes of the second plasma processing apparatus.

(Addendum 21)

A plasma processing system comprising:
a source RF signal generator configured to generate a source RF signal for plasma generation;
a first matching circuit coupled to the source RF signal generator;
a bias RF signal generator configured to generate a bias RF signal;
a second matching circuit coupled to the bias RF signal generator;
n plasma processing apparatuses (n is an integer greater than or equal to 2) coupled in parallel to the first matching circuit; and
(n−1) phase control circuits,
wherein the (n−1) phase control circuits are coupled in series between the second matching circuit and an n-th plasma processing apparatus among the n plasma processing apparatuses and are configured to sequentially shift a phase of the bias RF signal supplied from the bias RF signal generator through the second matching circuit,
a k-th (k is an integer of 1 to n−1) phase control circuit among the (n−1) phase control circuits is coupled to a k-th plasma processing apparatus and to a (k+1)-th plasma processing apparatus among the n plasma processing apparatuses,
a first plasma processing apparatus among the n plasma processing apparatuses includes a first plasma processing chamber and a first substrate support, in which the first substrate support is disposed in the first plasma processing chamber and includes one or a plurality of first lower electrodes, the source RF signal is supplied to the first plasma processing apparatus through the first matching circuit, and the bias RF signal is supplied to at least one of the one or the plurality of first lower electrodes of the first plasma processing apparatus through the second matching circuit, and
the (k+1)-th plasma processing apparatus among the n plasma processing apparatuses includes a (k+1)-th plasma processing chamber and a (k+1)-th substrate support, the (k+1)-th substrate support being disposed in the (k+1)-th plasma processing chamber and including one or a plurality of (k+1)-th lower electrodes, the source RF signal being supplied to the (k+1)-th plasma processing apparatus through the first matching circuit, and the bias RF signal of which the phase is shifted in the k-th phase control circuit among the (n−1) phase control circuits being supplied to at least one of the one or the plurality of (k+1)-th lower electrodes of the (k+1)-th plasma processing apparatus.

(Addendum 22)

The plasma processing system according to Addendum 21,
wherein the (n−1) phase control circuits are configured to sequentially shift the phase of the bias RF signal by 360 degrees/n.

(Addendum 23)

The plasma processing system according to Addendum 21 or 22, further comprising:
n first switches that switch whether or not each of the n plasma processing apparatuses is coupled to the first matching circuit, and
n second switches that switch whether or not each of the n plasma processing apparatuses is coupled to the second matching circuit.

(Addendum 24)

A plasma processing system comprising:
a source RF signal generator configured to generate a source RF signal for plasma generation;
a first matching circuit coupled to the source RF signal generator;
a voltage pulse generator configured to generate n (n is an integer greater than or equal to 2) sequences of voltage pulses, the phases of the n sequences of voltage pulses are different from each other; and
n plasma processing apparatuses,
wherein a k-th (k is an integer of 1 to n) plasma processing apparatus among the n plasma processing apparatuses includes a k-th plasma processing chamber and a k-th substrate support, the k-th substrate support is disposed in the k-th plasma processing chamber and includes one or a plurality of the k-th lower electrodes, the source RF signal is supplied to the k-th plasma processing apparatus through the first matching circuit, and a k-th sequence of voltage pulses in the n sequences of voltage pulses is supplied to at least one of the one or the plurality of k-th lower electrodes of the k-th plasma processing apparatus.

Each of the above embodiments is described for the purpose of description, and various modifications may be made without departing from the scope and purpose of the present disclosure. For example, it is possible to execute the present processing method using, in addition to the capacitively coupled substrate processing apparatus 1, a substrate processing apparatus, such as an inductively coupled plasma or a microwave plasma, which uses an arbitrary plasma source.

What is claimed is:

1. A plasma processing system comprising:
a source RF signal generator configured to generate a source RF signal for plasma generation;
a first matching circuit coupled to the source RF signal generator;
a bias RF signal generator configured to generate a bias RF signal;
a second matching circuit coupled to the bias RF signal generator;
a phase control circuit coupled to the second matching circuit and configured to shift a phase of the bias RF signal supplied from the bias RF signal generator through the second matching circuit;
a first plasma processing apparatus including a first plasma processing chamber and a first substrate support, the first substrate support being disposed in the first plasma processing chamber and including one or a plurality of first lower electrodes, the source RF signal being supplied to the first plasma processing apparatus through the first matching circuit, and the bias RF signal being supplied to at least one of the one or the plurality of first lower electrodes of the first plasma processing apparatus through the second matching circuit; and
a second plasma processing apparatus including a second plasma processing chamber and a second substrate support, the second substrate support being disposed in the second plasma processing chamber and including one or a plurality of second lower electrodes, the source RF signal being supplied to the second plasma processing apparatus through the first matching circuit, and the bias RF signal of which the phase is shifted in the phase control circuit being supplied to at least one of the one or the plurality of second lower electrodes of the second plasma processing apparatus.

2. The plasma processing system according to claim 1,
wherein the phase control circuit includes at least one inductor and at least one capacitor.

3. The plasma processing system according to claim 2,
wherein the phase control circuit includes at least one of a variable inductor or a variable capacitor.

4. The plasma processing system according to claim 3, further comprising:
a sensor configured to monitor the source RF signal between the source RF signal generator and the first matching circuit and output a monitoring result,
wherein the phase control circuit is configured to control one or both of inductance of the variable inductor and capacitance of the variable capacitor based on the monitoring result.

5. The plasma processing system according to claim 4,
wherein the sensor is a VI sensor configured to monitor a phase difference of a voltage and a current of the source RF signal.

6. The plasma processing system according to claim 4,
wherein the sensor is a directional coupler configured to monitor a reflected wave of the source RF signal.

7. The plasma processing system according to claim 3,
wherein the phase control circuit is configured to control one or both of inductance of the variable inductor and capacitance of the variable capacitor before or after plasma processing in the second plasma processing apparatus.

8. The plasma processing system according to claim 3,
wherein the phase control circuit is configured to control inductance of the variable inductor and capacitance of the variable capacitor during plasma processing in the second plasma processing apparatus.

9. The plasma processing system according to claim 1,
wherein a phase difference between the bias RF signal and the bias RF signal of which the phase is shifted is 180 degrees.

10. The plasma processing system according to claim 1,
wherein the first plasma processing apparatus includes a first upper electrode disposed above the first substrate support,
the second plasma processing apparatus includes a second upper electrode disposed above the second substrate support,
the first matching circuit is coupled to at least one of the one or the plurality of first lower electrodes or the first upper electrode and to at least one of the one or the plurality of second lower electrodes or the second upper electrode,
the second matching circuit is coupled to at least one of the one or the plurality of first lower electrodes, and
the phase control circuit is coupled to at least one of the one or the plurality of second lower electrodes.

11. The plasma processing system according to claim 1,
wherein the first plasma processing apparatus includes a first antenna disposed above the first plasma processing chamber,
the second plasma processing apparatus includes a second antenna disposed above the second plasma processing chamber,
the first matching circuit is coupled to the first antenna and to the second antenna,
the second matching circuit is coupled to at least one of the one or the plurality of first lower electrodes, and
the phase control circuit is coupled to at least one of the one or the plurality of second lower electrodes.

12. The plasma processing system according to claim 1,
wherein the source RF signal has a frequency within a range of 10 MHz to 120 MHz.

13. The plasma processing system according to claim 1,
wherein the bias RF signal has a frequency within a range of 100 kHz to 20 MHz.

14. The plasma processing system according to claim 1,
wherein the bias RF signal has a frequency within a range of 400 kHz to 4 MHz.

15. The plasma processing system according to claim 1,
wherein the source RF signal is a continuous wave having a first frequency.

16. The plasma processing system according to claim 1,
wherein the source RF signal is a pulse wave periodically including a plurality of first electrical pulses, and
each of the plurality of first electrical pulses includes a continuous wave having a first frequency.

17. The plasma processing system according to claim 1,
wherein the bias RF signal is a continuous wave having a second frequency.

18. The plasma processing system according to claim 1,
wherein the bias RF signal is a pulse wave periodically including a plurality of second electrical pulses, and
each of the plurality of second electrical pulses includes a continuous wave having a second frequency.

19. A plasma processing method executed in a plasma processing system including a first plasma processing apparatus and a second plasma processing apparatus, the plasma processing method comprising:
generating a first RF signal having a first frequency;
generating a second RF signal having a second frequency lower than the first frequency;
shifting a phase of the second RF signal;
supplying the first RF signal to the first plasma processing apparatus and to the second plasma processing apparatus;
supplying the second RF signal to the first plasma processing apparatus; and
supplying the second RF signal of which the phase is shifted to the second plasma processing apparatus.

20. A plasma processing system comprising:
an RF signal generator configured to generate an RF signal;
a matching circuit coupled to the RF signal generator;
a voltage pulse generator configured to generate a sequence of voltage pulses;
a phase control circuit configured to shift phases of the sequence of voltage pulses supplied from the voltage pulse generator;
a first plasma processing apparatus including a first plasma processing chamber and a first substrate support, the first substrate support being disposed in the first plasma processing chamber and including one or a plurality of first lower electrodes, the RF signal being supplied to the first plasma processing apparatus through the matching circuit, and the sequence of voltage pulses being supplied to the one or the plurality of first lower electrodes of the first plasma processing apparatus from the voltage pulse generator; and
a second plasma processing apparatus including a second plasma processing chamber and a second substrate support, the second substrate support being disposed in the second plasma processing chamber and including one or a plurality of second lower electrodes, the RF signal being supplied to the second plasma processing apparatus through the matching circuit, and the sequence of voltage pulses of which the phases are shifted in the phase control circuit being supplied to at least one of the one or the plurality of second lower electrodes of the second plasma processing apparatus.

21. A plasma processing system comprising:
a source RF signal generator configured to generate a source RF signal for plasma generation;
a first matching circuit coupled to the source RF signal generator;
a bias RF signal generator configured to generate a bias RF signal;
a second matching circuit coupled to the bias RF signal generator;
n plasma processing apparatuses (n is an integer greater than or equal to 2) coupled in parallel to the first matching circuit; and
(n−1) phase control circuits,
wherein the (n−1) phase control circuits are coupled in series between the second matching circuit and an n-th plasma processing apparatus among the n plasma processing apparatuses and are configured to sequentially shift a phase of the bias RF signal supplied from the bias RF signal generator through the second matching circuit,
a k-th (k is an integer of 1 to n−1) phase control circuit among the (n−1) phase control circuits is coupled to a k-th plasma processing apparatus and to a (k+1)-th plasma processing apparatus among the n plasma processing apparatuses,
a first plasma processing apparatus among the n plasma processing apparatuses includes a first plasma processing chamber and a first substrate support, in which the first substrate support is disposed in the first plasma processing chamber and includes one or a plurality of first lower electrodes, the source RF signal is supplied to the first plasma processing apparatus through the first matching circuit, and the bias RF signal is supplied to at least one of the one or the plurality of first lower electrodes of the first plasma processing apparatus through the second matching circuit, and
the (k+1)-th plasma processing apparatus among the n plasma processing apparatuses includes a (k+1)-th plasma processing chamber and a (k+1)-th substrate support, the (k+1)-th substrate support being disposed in the (k+1)-th plasma processing chamber and including one or a plurality of (k+1)-th lower electrodes, the source RF signal being supplied to the (k+1)-th plasma processing apparatus through the first matching circuit, and the bias RF signal of which the phase is shifted in the k-th phase control circuit among the (n−1) phase control circuits being supplied to at least one of the one or the plurality of (k+1)-th lower electrodes of the (k+1)-th plasma processing apparatus.

22. The plasma processing system according to claim 21,
wherein the (n−1) phase control circuits are configured to sequentially shift the phase of the bias RF signal by 360 degrees/n.

23. The plasma processing system according to claim 21, further comprising:
n first switches that switch whether or not each of the n plasma processing apparatuses is coupled to the first matching circuit; and
n second switches that switch whether or not each of the n plasma processing apparatuses is coupled to the second matching circuit.

24. A plasma processing system comprising:
a source RF signal generator configured to generate a source RF signal for plasma generation;
a first matching circuit coupled to the source RF signal generator;
a voltage pulse generator configured to generate n (n is an integer greater than or equal to 2) sequences of voltage pulses, the phases of the n sequences of voltage pulses are different from each other; and
n plasma processing apparatuses,
wherein a k-th (k is an integer of 1 to n) plasma processing apparatus among the n plasma processing apparatuses includes a k-th plasma processing chamber and a k-th substrate support, the k-th substrate support is disposed in the k-th plasma processing chamber and includes one or a plurality of the k-th lower electrodes, the source RF signal is supplied to the k-th plasma processing apparatus through the first matching circuit, and a k-th sequence of voltage pulses in the n sequences of voltage pulses is supplied to at least one of the one or the plurality of k-th lower electrodes of the k-th plasma processing apparatus.
